(19) United States
(12) Patent Application Publication
(10) Pub. No.: US 2022/0271066 A1
(43) Pub. Date: Aug. 25, 2022

(54) TRANSISTOR ARRAY SUBSTRATE, METHOD OF MANUFACTURING TRANSISTOR ARRAY SUBSTRATE, LIQUID CRYSTAL DISPLAY APPARATUS, AND ELECTRIC EQUIPMENT

(71) Applicants: SONY GROUP CORPORATION, TOKYO (JP); SONY SEMICONDUCTOR SOLUTIONS CORPORATION, KANAGAWA (JP)

(72) Inventors: TAKEOMI MORITA, KUMAMOTO (JP); SHINYA INAGE, KUMAMOTO (JP); HITOSHI TSUNO, TOKYO (JP); NOBUHIKO ODA, KUMAMOTO (JP); YOSHIHIKO KAJIYA, TOKYO (JP)

(21) Appl. No.: 17/631,207

(22) PCT Filed: Jun. 19, 2020
(86) PCT No.: PCT/JP2020/024091

§ 371 Date: Jan. 28, 2022

(30) Foreign Application Priority Data
Aug. 6, 2019 (JP) 2019-144533

(51) Int. Cl. H01L 27/12; G02F 1/1368; G02F 1/1362

(52) U.S. Cl. CPC H01L 27/1251; H01L 27/1244; G02F 1/1368; G02F 1/136286; H01L 27/1259

(57) ABSTRACT

A transistor array substrate includes a scan line formed on a support substrate, a capacitive section formed above the scan line, and a thin film transistor formed above the capacitive section, in which a perimeter of the thin film transistor is surrounded by a wall-shaped horizontal light-blocking film that extends in a normal direction with respect to the support substrate and is in contact with a surface of an electrode that is an uppermost layer of the capacitive section, and an upper light-blocking film is formed above the thin film transistor.

### TECHNICAL FIELD

The present disclosure pertains to a transistor array substrate, a method of manufacturing a transistor array substrate, a liquid crystal display apparatus, and electronic equipment.

### BACKGROUND ART

A liquid crystal display apparatus having a configuration in which a liquid crystal material layer is sandwiched between a transistor array substrate and a counter substrate, with thin film transistors as switching elements being disposed in a matrix shape in the transistor array substrate and a counter electrode being provided in the counter substrate, is known. The liquid crystal display apparatus displays an image by causing pixels to operate as optical shutters (light valves). In recent years, higher definition and higher luminance are both required of liquid crystal display apparatuses. Accordingly, effort to improve a pixel aperture ratio according to pattern miniaturization is continuing.

In an active matrix method liquid crystal display apparatus, a switching element is set to a non-conducting state after a voltage is applied to a pixel via the switching element. Display is performed by a capacitive section of the pixel holding the voltage. Accordingly, when a leakage current flows to the switching element which should be in a non-conducting state, the voltage of the capacitive section changes, and display quality deteriorates as a result. In a case of using a thin film transistor as a switching element, when outside light is incident on the thin film transistor, carriers are induced and the leakage current increases. Accordingly, a method for reducing leakage in a thin film transistor by shielding the thin film transistor is known (for example, refer to PTL 1).

### CITATION LIST

### Patent Literature

[PTL 1]
Japanese Patent Laid-open No. 2004-45576

### SUMMARY

### Technical Problem

The ratio occupied by a portion of a gap between pixel electrodes increases as the pixel pitch decreases. Accordingly, qualitatively, the aperture ratio decreases the smaller the pixel pitch. In addition, leakage decreases the greater the area of a region for shielding a thin film transistor but this is a factor in a decrease of the aperture ratio. Accordingly, more effectively shielding a thin film transistor while preventing a decrease of the aperture ratio is required.

Accordingly, an objective of the present disclosure is to provide a transistor array substrate which can more effectively shield a thin film transistor while preventing a decrease of the aperture ratio, a method of manufacturing this transistor array substrate, a liquid crystal display apparatus provided with this transistor array substrate, and electronic equipment provided with this liquid crystal display apparatus.

### Solution to Problem

A transistor array substrate according to the present disclosure for achieving the objective described above includes a scan line formed on a support substrate, a capacitive section formed above the scan line; and a thin film transistor formed above the capacitive section, in which a perimeter of the thin film transistor is surrounded by a wall-shaped horizontal light-blocking film that extends in a normal direction with respect to the support substrate and is in contact with a surface of an electrode that is an uppermost layer of the capacitive section, and an upper light-blocking film is formed above the thin film transistor.

A method of manufacturing a transistor array substrate according to the present disclosure for achieving the objective described above includes a step of, after a scan line is formed on a support substrate, forming a capacitive section above the scan line and next forming a thin film transistor above the capacitive section, a step of subsequently forming a wall-shaped horizontal light-blocking film that extends in a normal direction with respect to the support substrate and is in contact with an electrode that is an uppermost layer of the capacitive section, at a perimeter of the thin film transistor, and a step of next forming an upper light-blocking film above the thin film transistor.

A liquid crystal display apparatus according to the present disclosure for achieving the objective described above includes a transistor array substrate, a counter substrate disposed so as to oppose the transistor array substrate, and a liquid crystal material layer enclosed between the transistor array substrate and the counter substrate, in which the transistor array substrate includes a scan line formed on a support substrate, a capacitive section formed above the scan line, and a thin film transistor formed above the capacitive section, a perimeter of the thin film transistor is surrounded by a wall-shaped horizontal light-blocking film that extends in a normal direction with respect to the support substrate and is in contact with an electrode that is an uppermost layer of the capacitive section, and an upper light-blocking film is formed above the thin film transistor.

Electronic equipment according to the present disclosure for achieving the abovementioned objective includes a transistor array substrate, a counter substrate disposed so as to oppose the transistor array substrate, and a liquid crystal material layer enclosed between the transistor array substrate and the counter substrate, in which the transistor array substrate includes a scan line formed on a support substrate, a capacitive section formed above the scan line, and a thin film transistor formed above the capacitive section, a perimeter of the thin film transistor is surrounded by a wall-shaped horizontal light-blocking film that extends in a normal direction with respect to the support substrate and is in contact with an electrode that is an uppermost layer of the capacitive section, and an upper light-blocking film is formed above the thin film transistor.

### BRIEF DESCRIPTION OF DRAWINGS

FIG. 1 is a schematic view for describing a liquid crystal display apparatus which uses a transistor array substrate according to a first embodiment of the present disclosure.

FIG. 2A is a schematic cross-section view for describing a basic configuration of the liquid crystal display apparatus.

FIG. 2B is a schematic circuit diagram for describing a pixel in the liquid crystal display apparatus.

FIG. 3 is a schematic partial plan view for describing the transistor array substrate according to the present disclosure.

FIGS. 4A and 4B are views for describing a cross-sectional structure in the transistor array substrate. FIG. 4A is a schematic plan view which includes a portion between pixel electrodes in the transistor array substrate. FIG. 4B is a schematic cross-section view of a portion indicated by A-A in FIG. 4A.

FIGS. 5A and 5B are views for describing a cross-sectional structure in the transistor array substrate. FIG. 5A is a schematic plan view which includes a portion between pixel electrodes in the transistor array substrate. FIG. 5B is a schematic cross-section view of a portion indicated by B-B in FIG. 5A.

FIGS. 6A and 6B are views for describing a cross-sectional structure in the transistor array substrate. FIG. 6A is a schematic plan view which includes a portion between pixel electrodes in the transistor array substrate. FIG. 6B is a schematic cross-section view of a portion indicated by C-C in FIG. 6A.

FIG. 7 is a schematic partial plan view of a substrate, etc. and is for describing a method of manufacturing the transistor array substrate.

FIG. 8 is a schematic partial plan view of the substrate, etc. and is for describing the method of manufacturing the transistor array substrate, continuing from FIG. 7.

FIG. 9 is a schematic partial plan view of the substrate, etc. and is for describing the method of manufacturing the transistor array substrate, continuing from FIG. 8.

FIG. 10 is a schematic partial plan view of the substrate, etc. and is for describing the method of manufacturing the transistor array substrate, continuing from FIG. 9.

FIG. 11 is a schematic partial plan view of the substrate, etc. and is for describing the method of manufacturing the transistor array substrate, continuing from FIG. 10.

FIG. 12 is a schematic partial plan view of the substrate, etc. and is for describing the method of manufacturing the transistor array substrate, continuing from FIG. 11.

FIG. 13 is a schematic partial plan view of the substrate, etc. and is for describing the method of manufacturing the transistor array substrate, continuing from FIG. 12.

FIG. 14A and FIG. 14B are views for describing cross-sectional shapes for a horizontal light-blocking film and contacts which are formed at the same time as the horizontal light-blocking film. FIG. 14A is an enlarged plan view of a portion of the transistor array substrate to which the step illustrated in FIG. 13 has been performed. FIG. 14B is a schematic cross-section view of a portion indicated by D-D in FIG. 14A.

FIG. 15 is a schematic partial plan view of the substrate, etc. and is for describing the method of manufacturing the transistor array substrate, continuing from FIG. 13.

FIG. 16 is a schematic partial plan view of the substrate, etc. and is for describing the method of manufacturing the transistor array substrate, continuing from FIG. 15.

FIG. 17 is a schematic partial plan view of the substrate, etc. and is for describing the method of manufacturing the transistor array substrate, continuing from FIG. 16.

FIG. 18 is a schematic partial plan view of the substrate, etc. and is for describing the method of manufacturing the transistor array substrate, continuing from FIG. 17.

FIG. 19 is a schematic partial plan view of the substrate, etc. and is for describing the method of manufacturing the transistor array substrate, continuing from FIG. 18.

FIG. 20 is a schematic partial plan view of the substrate, etc. and is for describing the method of manufacturing the transistor array substrate, continuing from FIG. 19.

FIG. 21A and FIG. 21B are views for describing a cross-sectional structure in a transistor array substrate used in a liquid crystal display apparatus, according to a first modification example. FIG. 21A is a schematic plan view which includes a portion between pixel electrodes in the transistor array substrate. FIG. 21B is a schematic cross-section view of a portion indicated by E-E in FIG. 21A.

FIG. 22A and FIG. 22B are views for describing a cross-sectional structure in a transistor array substrate used in a liquid crystal display apparatus, according to a second modification example. FIG. 22A is a schematic plan view which includes a portion between pixel electrodes in the transistor array substrate. FIG. 22B is a schematic cross-section view of a portion indicated by F-F in FIG. 22A.

FIG. 23 is a conceptual diagram of a projection-type display apparatus.

FIG. 24 depicts external views of a lens interchangeable single lens reflex type digital still camera, with FIG. 24A illustrating a front view thereof, and FIG. 24B illustrating a rear view thereof.

FIG. 25 is an external view of a head-mounted display.

FIG. 26 is an external view of a see-through head-mounted display.

### DESCRIPTION OF EMBODIMENTS

With reference to the drawings, the present disclosure is described below on the basis of embodiments. The present disclosure is not limited to the embodiments, and various numbers and materials in the embodiments are examples. In the following description, the same reference sign is used for the same elements or elements having the same function, and duplicate descriptions are omitted. Note that the description is made in the following order.

1. Description generally pertaining to a transistor array substrate, a method of manufacturing a transistor array substrate, a liquid crystal display apparatus, and electronic equipment, according to the present disclosure.

2. First embodiment

3. First modification example

4. Second modification example

5. Description of electric equipment, other

### [Description Generally Pertaining to a Transistor Array Substrate, a Method of Manufacturing a Transistor Array Substrate, a Liquid Crystal Display Apparatus, and Electronic Equipment, According to the Present Disclosure]

In the following description, a transistor array substrate according to the present disclosure, a transistor array substrate obtained in accordance with a method of manufacturing a transistor array substrate according to the present disclosure, and a transistor array substrate used in a liquid crystal display apparatus according to the present disclosure (includes electronic equipment provided with a liquid crystal display apparatus according to the present disclosure) may be simply referred to as a transistor array substrate according to the present disclosure.

In a transistor array substrate according to the present disclosure, it is possible to have a configuration in which a horizontal light-blocking film and an upper light-blocking film include an electrically-conductive material having a light-blocking property. As a material having a light-blocking property (includes material having a light-absorption property, the same applies below), it is possible to exemplify material such as silicon (Si), tungsten (W), and tungsten silicide (WSiₓ).

In such a case, it is possible to have a configuration in which a portion of the horizontal light-blocking film is formed so as to be in contact with an electrode surface of a capacitive section in a state where a semiconductor material layer which makes up a thin film transistor is penetrated. Alternatively, it is possible to have a configuration in which, in a portion where the horizontal light-blocking film penetrates the semiconductor material layer, a contact surface between the horizontal light-blocking film and the semiconductor material layer has a tapered shape.

In a transistor array substrate of the present disclosure including various desirable configurations described above, it is possible to have a configuration in which the gate electrode of a thin film transistor is formed extending in a direction in which a scan line extends, and the upper light-blocking film is formed so as to cover above the thin film transistor, and also cover above a portion of the gate electrode positioned outside a region surrounded by the horizontal light-blocking film. In such a case, it is possible to have a configuration in which the thin film transistor is further provided with a gate shield electrode formed on a surface side of a semiconductor material layer that makes up the thin film transistor, the surface side being opposite to a surface on the gate electrode side.

In a transistor array substrate according to the present disclosure which includes various desirable configurations described above, it is possible to have a configuration in which an electrode that makes up the capacitive section includes an electrically-conductive material having a light-blocking property. There is no particular limitation on the number of electrodes which make up the capacitive section. For example, there may be a configuration in which two electrodes are laminated and face each other, or there may be a configuration in which three electrodes are laminated and face each other. In a case of the latter configuration, it is possible to configure a capacitive section to which electrical connections are made in parallel by applying a common voltage to a second electrode sandwiched between first and third electrodes, and applying a pixel voltage to the first and third electrodes.

In a transistor array substrate according to the present disclosure including various desirable configurations described above, it is possible for a shield electrode to be formed above the upper light-blocking film. In such a case, it is possible to have a configuration in which a common potential is applied to the shield electrode.

In a transistor array substrate according to the present disclosure including various desirable configurations described above, it is possible to have a configuration in which a pixel voltage is applied to an electrode which is the uppermost layer of the capacitive section. Alternatively, it is possible to have a configuration in which a common potential is applied to the electrode that is the uppermost layer of the capacitive section.

In a transistor array substrate according to the present disclosure including various desirable configurations described above, it is possible to have a configuration in which a common potential line and a signal line are further formed above the upper light-blocking film. Note that there is no particular limitation on a lamination relation between the common potential line and the signal line, and it may be that there is a configuration in which the common potential line is disposed above the signal line, or it may be that there is a configuration in which the signal line is disposed above the common potential line.

In a transistor array substrate according to the present disclosure including various desirable configurations described above, it is possible to have a configuration in which a pixel electrode to which a pixel voltage held by the capacitive section is applied is further provided. In the case of a transistor array substrate used for a transparent type liquid crystal display apparatus, it is possible to form the pixel electrode using a transparent electrically conductive material such as indium tin oxide (ITO) or indium zinc oxide (IZO).

As described above, a manufacturing method for manufacturing a transistor array substrate according to the present disclosure including various desirable configurations described above includes a step of, after a scan line is formed on a support substrate, forming a capacitive section above the scan line and next forming a thin film transistor above the capacitive section, a step of subsequently forming a wall-shaped horizontal light-blocking film that extends in a normal direction with respect to the support substrate and is in contact with an electrode that is an uppermost layer of the capacitive section, at a perimeter of the thin film transistor, and a step of next forming an upper light-blocking film above the thin film transistor.

When manufacturing a thin film transistor array substrate, it is necessary to have a process at approximately 1000° C., for example, in a step of forming a thin film transistor. However, thereafter it is possible to perform a series of steps with a process at approximately 400° C., for example. In a case in which a light-blocking film is formed by a material such as tungsten silicide, for example, a light-blocking property is reduced when the light-blocking film is exposed to a high temperature. Accordingly, it is possible to avoid a reduction in the light-blocking property due to exposure to a high temperature process by forming the horizontal light-blocking film and the upper light-blocking film after a step of forming the thin film transistor.

As described above, a liquid crystal display apparatus having a transistor array substrate according to the present disclosure including various desirable configurations described above includes a transistor array substrate, a counter substrate disposed so as to oppose the transistor array substrate, and a liquid crystal material layer enclosed between the transistor array substrate and the counter substrate.

It is possible to use a substrate including a transparent material such as a glass material as the counter substrate. In the counter substrate, it is possible to form a counter electrode using a transparent electrically conductive material such as indium tin oxide (ITO) or indium zinc oxide (IZO). The counter electrode functions as a common electrode with respect to each pixel in the liquid crystal display apparatus.

As the transistor array substrate, it is possible to use a substrate including a transparent material such as a glass material, or a substrate including a semiconductor material such as silicon. It is possible to configure a thin film transistor which configures a switching element according to processing for forming, for example, a semiconductor material layer on a substrate.

Similarly to the counter electrode, it is possible to form a pixel electrode using a transparent electrically conductive material such as ITO or IZO. Note that, depending on the case, it is possible to use a metal film which has been made thin to the extent that the metal film has optical transparency.

There is no particular limitation on material for configuring various wiring, electrodes, or contacts, and it is possible to use a metal material such as aluminum (Al), an aluminum alloy such as Al—Cu or Al—Si, tungsten (W), or a tungsten alloy such as tungsten silicide (WSiₓ), for example.

A material which makes up an insulation layer or an insulating film is not limited in particular, and it is possible to use an inorganic material such as silicon oxide, silicon oxynitride, or silicon nitride, or an organic material such as a polyimide.

The liquid crystal display apparatus may have a configuration for displaying a monochrome image, or may have a configuration for displaying a color image. As a value for pixels (pixels) in a liquid crystal display apparatus, it is possible to exemplify several image resolutions such as (3840, 2160) or (7680, 4320) in addition to U-XGA (1600, 1200), HD-TV (1920, 1080), or Q-XGA (2048, 1536), but there is no limitation to these values.

In addition, as electronic equipment provided with a liquid crystal display apparatus according to the present disclosure, it is possible to exemplify a direct view type display apparatus or a projection type display apparatus as well as various electric equipment provided with an image display function.

Various conditions in the present specification are satisfied in a case of being substantial established, in addition to a case of being strictly established. The presence of various variations arising during design or manufacture is permitted. In addition, each drawing used in the following description is schematic, and does not illustrate actual dimensions or ratios thereof.

### First Embodiment

A first embodiment pertains to a transistor array substrate, a method of manufacturing a transistor array substrate, a liquid crystal display apparatus, and electronic equipment which are according to the present disclosure.

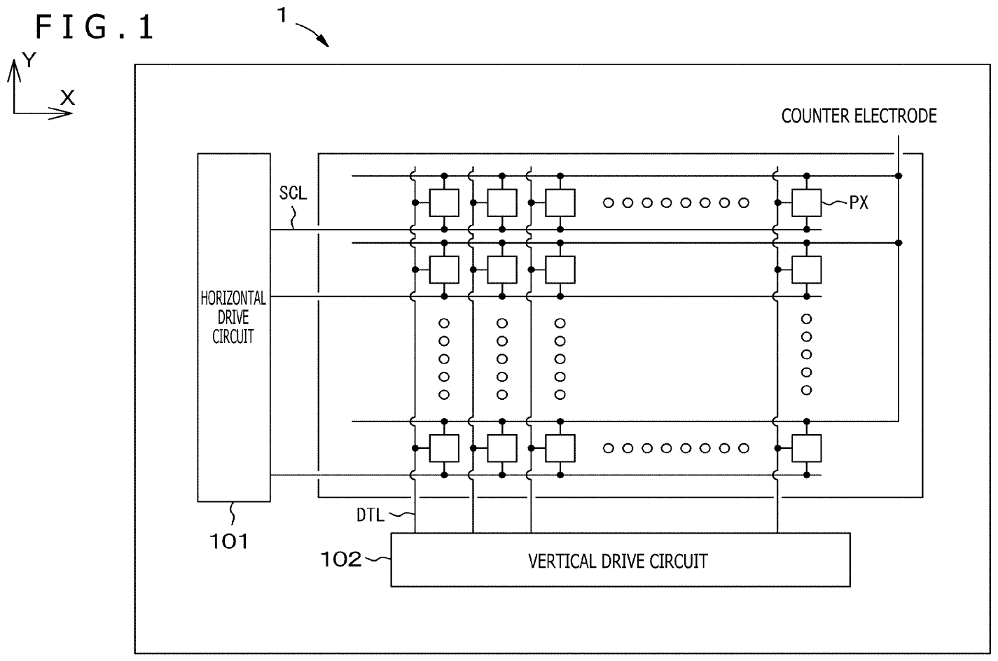

FIG. 1 is a schematic view for describing a liquid crystal display apparatus using a transistor array substrate according to a first embodiment of the present disclosure.

A liquid crystal display apparatus according to the first embodiment is an active matrix method liquid crystal display apparatus. As illustrated in FIG. 1, a liquid crystal display apparatus 1 is provided with pixels PX disposed in a matrix shape, various circuits such as a horizontal drive circuit 101 and a vertical drive circuit 102 which are for driving the pixels PX. A reference sign SCL is a scan line for scanning pixels PX, and a reference sign DTL is a signal line for supplying various voltages to pixels PX. For the pixels PX, for example, a total of M×N pixels are disposed in a matrix shape, with M pixels PX in the horizontal direction and N pixels PX in the vertical direction. A counter electrode illustrated in FIG. 1 is provided as a common electrode for each liquid crystal cell. Note that, in the example illustrated in FIG. 1, the horizontal drive circuit 101 and the vertical drive circuit 102 are each disposed on one end side of the liquid crystal display apparatus 1, but this is merely an example.

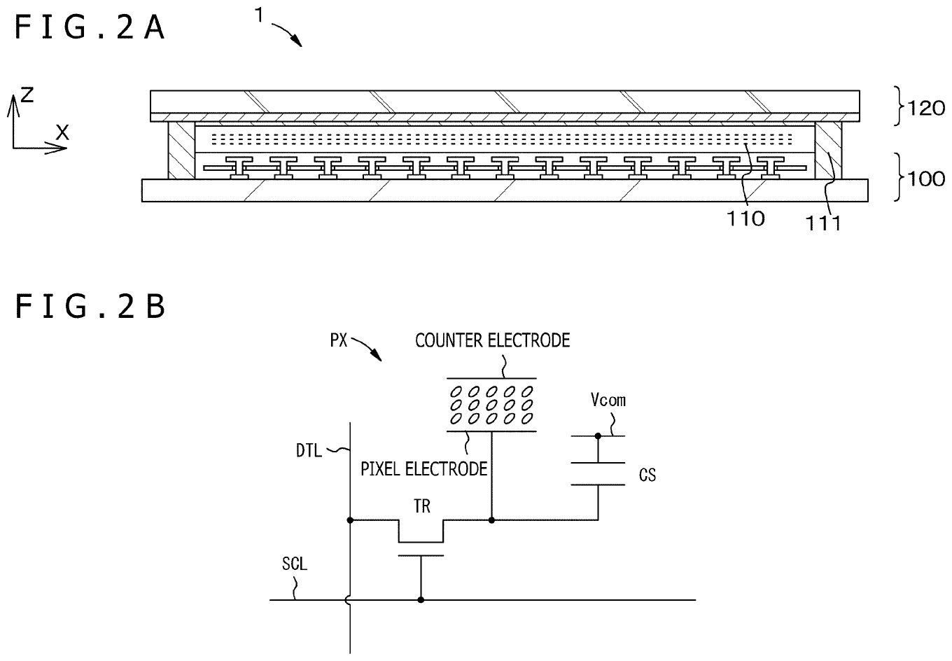

FIG. 2A is a schematic cross-section view for describing a basic configuration of a liquid crystal display apparatus. FIG. 2B is a schematic circuit diagram for describing a pixel in the liquid crystal display apparatus.

As illustrated in FIG. 2A, the liquid crystal display apparatus 1 includes a transistor array substrate 100, a counter substrate 120 disposed so as to oppose the transistor array substrate, and a liquid crystal material layer 110 enclosed between the transistor array substrate and the counter substrate. The transistor array substrate 100 and the counter substrate 120 are sealed by a seal part 111. The seal part 111 is annular and surrounds the liquid crystal material layer 110.

As described below, the transistor array substrate 100 is configured by various components being laminated, for example, on a support substrate including, for example, a glass material. The liquid crystal display apparatus 1 is a transparent type liquid crystal display apparatus.

A counter electrode including a transparent electrically conductive material such as ITO, for example, is provided on the counter substrate 120. More specifically, the counter substrate 120 is configured from, for example, a rectangular substrate including a transparent glass, for example, a counter electrode provided on the surface of the substrate on the liquid crystal material layer 110 side, and an alignment film provided on the counter electrode. In addition, a polarizing plate, etc. is, for example, pasted as appropriate to the transistor array substrate 100 or the counter substrate 120. Note that, for convenience of illustration, the transistor array substrate 100 and the counter substrate 120 in FIG. 2A are illustrated in a simplified manner.

As illustrated in FIG. 2B, a liquid crystal cell which makes up a pixel PX is configured by a pixel electrode provided on the transistor array substrate 100, and the liquid crystal material layer or the counter electrode at a portion corresponding to the pixel electrode. In order to prevent deterioration of the liquid crystal material layer 110, when the liquid crystal display apparatus 1 is driven, a common potential V_{com} having a positive polarity or a negative polarity is alternatingly applied to the counter electrode. Note that, elements in a pixel PX excluding the liquid crystal material layer and the counter electrode are formed in the transistor array substrate 100 illustrated in FIG. 2A.

As is clear from the wiring relation in FIG. 2B, a pixel voltage supplied from the signal line DTL is applied to the pixel electrode via a thin film transistor TR which is set to a conductive state according to a scan signal on the scan line SCL. Because the pixel electrode and one electrode of a capacitive section CS are electrically connected, the pixel voltage is also applied to the one electrode of the capacitive section CS. Note that the common potential V_{com} is applied to the other electrode of the capacitive section. In this configuration, even after the thin film transistor TR is set to a non-conducting state, the voltage of the pixel electrode is held by the capacitance of the liquid crystal cell and the capacitive section CS.

However, in a case where the thin film transistor TR is set to the non-conducting state, a leakage current increases when outside light, for example, is incident on the thin film transistor TR. Specifically, the charge held by the capacitive section CS flows out via the signal line DTL, and display quality deteriorates as a result.

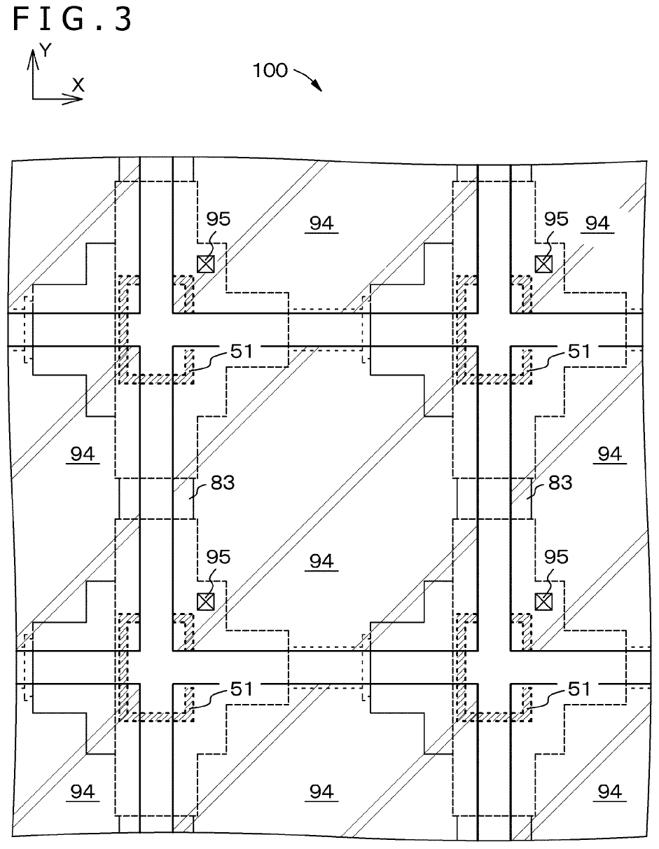

Description is given in detail with reference to FIG. 3 through FIG. 20, but in the display apparatus 1 according to the first embodiment, a scan line is formed on the support substrate which makes up the transistor array substrate 100. A capacitive section is formed above the scan line, and the thin film transistor is formed above the capacitive section. Then, a perimeter of the thin film transistor is surrounded by a wall-shaped horizontal light-blocking film that extends in a normal direction with respect to the support substrate and is in contact with a surface of an electrode that is the uppermost layer of the capacitive section. Furthermore, configuration is taken so that an upper light-blocking film is formed above the thin film transistor. As a result, it is possible to more effectively shield the thin film transistor while preventing a decrease of an aperture ratio.

FIG. 3 is a schematic partial plan view for describing a transistor array substrate according to the present disclosure.

Pixel electrodes 94 formed by dividing a transparent conductive film, for example, into a matrix shape are disposed on the transistor array substrate 100. A reference sign 95 indicates a contact for a lower layer side for a pixel electrode 94. A thin film transistor (not illustrated) is formed between adjacent pixel electrodes 94. A Reference sign 51 indicates a wall-shaped horizontal light-blocking film which extends in a normal direction with respect to the support substrate and is in contact with the surface of the electrode which is the uppermost layer of the capacitive section. A horizontal light-blocking film 51 includes an electrically-conductive material having a light-blocking property. It is similar for an upper light-blocking film described below.

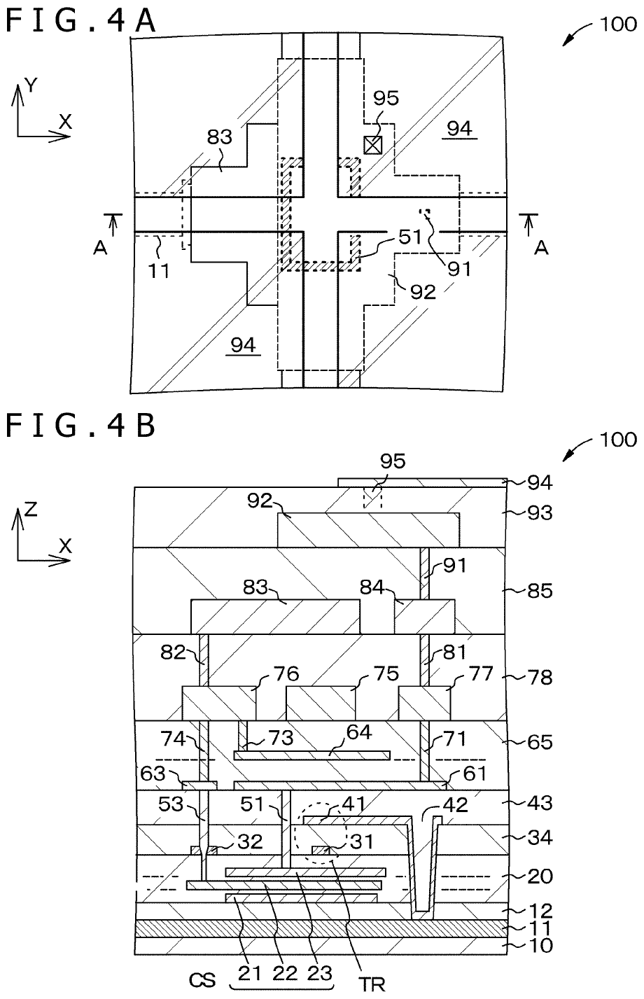

Note that, because many components are laminated, readability is impaired when all elements are illustrated in a plan view. Accordingly, only some elements are displayed in the plan view illustrated in FIG. 3. A detailed disposition relation for each element is described in detail with reference to FIG. 4 through FIG. 20.

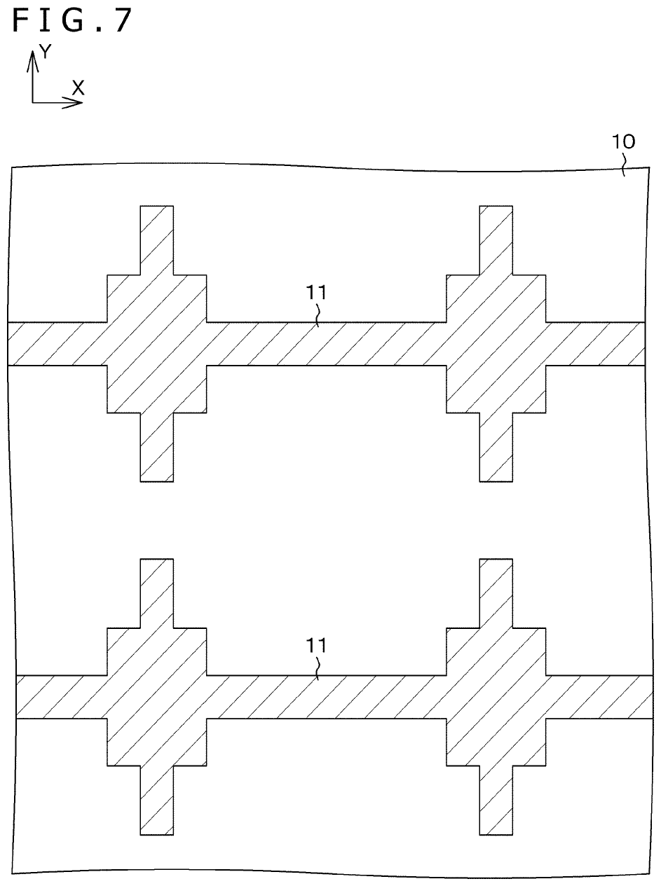

Firstly, description is given with reference to FIG. 4 through FIG. 6 regarding the disposition relation for each element. Note that FIG. 7 through FIG. 20, which are for describing a method of manufacturing a transistor array substrate, are referred to as appropriate to give a description regarding the planar shape of each element.

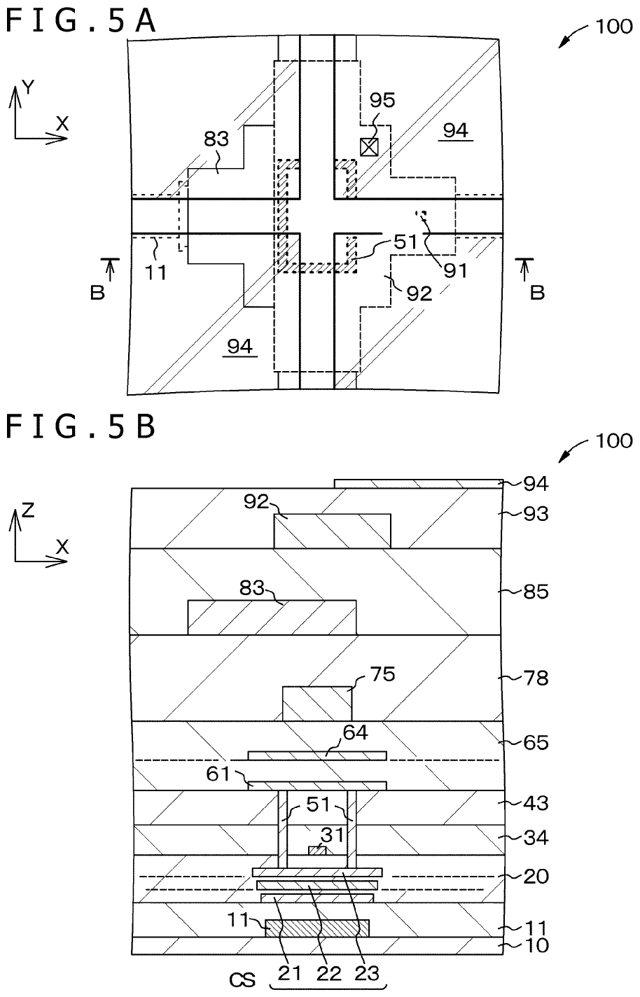

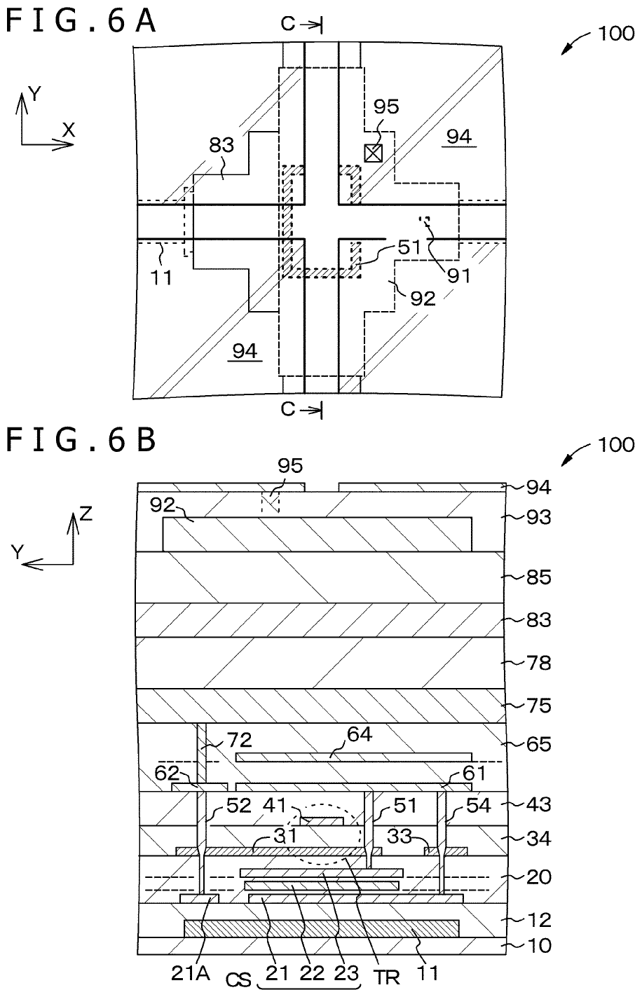

FIG. 4A, FIG. 5A, and FIG. 6A are schematic plan views which include a portion between pixel electrodes in the transistor array substrate. FIG. 4B is a schematic cross-section view of a portion indicated by A-A in FIG. 4A. FIG. 5B is a schematic cross-section view of a portion indicated by B-B in FIG. 5A. FIG. 6B is a schematic cross-section view of a portion indicated by C-C in FIG. 6A.

Firstly, description is given with reference to FIG. 4B, FIG. 5B, and FIG. 6B. Scan lines 11 (corresponds to SCL in FIG. 1) extending in the X direction are formed on a support substrate 10 which makes up the transistor array substrate 100. Portions to which hatching has been added in FIG. 7 indicate the planar shape of the scan lines 11.

An insulating film 12 is formed on the entire surface including on the scan lines 11, and, on the insulating film 12, an electrode 21, an electrode 22, and an electrode 23 are disposed so as to be embedded in an insulation layer 20. The insulation layer 20 is formed by laminating a plurality of material layers, and there is separation by an insulator between the electrode 21 and the electrode 22 and between the electrode 22 and the electrode 23. The electrodes 21, 22, and 23 make up a capacitive section CS formed above a scan line. The electrodes 21, 22, and 23 which make up the capacitive section CS include an electrically-conductive material having a light-blocking property.

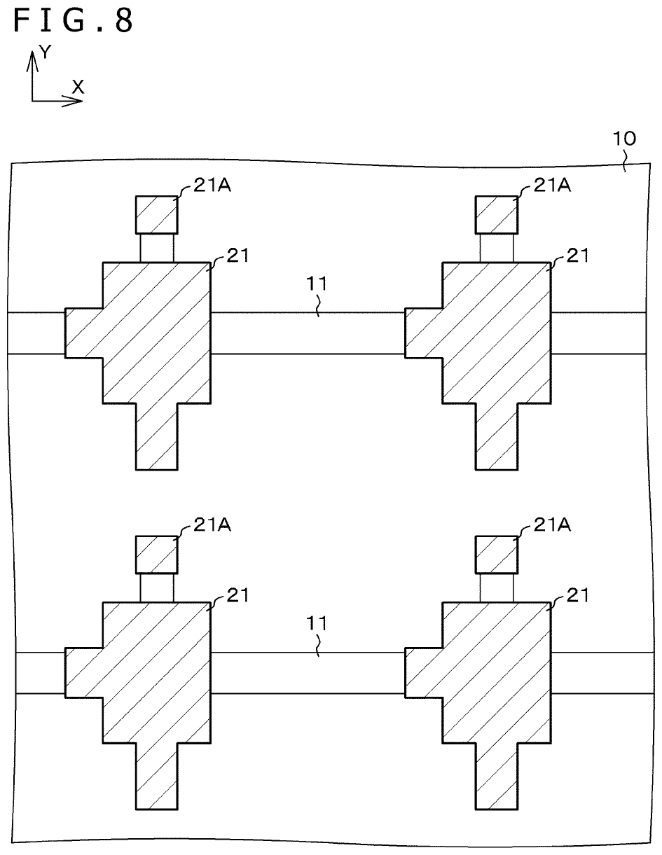

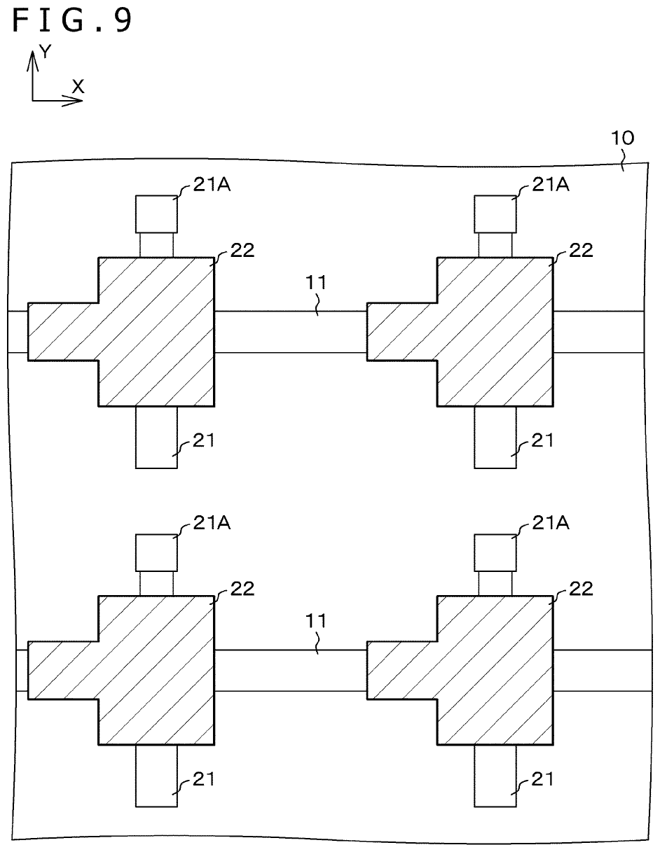

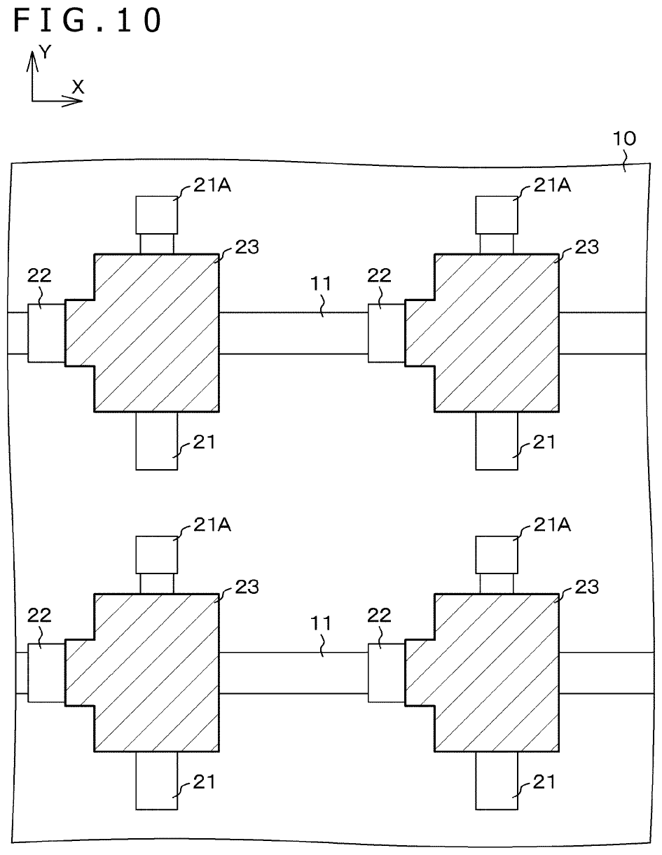

Note that an electrode 21A illustrated in FIG. 6B has the purpose of functioning as an etching stop layer and is formed in the same layer as the electrode 21. Portions to which hatching has been added in FIG. 8 indicate the planar shape of the electrodes 21 and 21A. Portions to which hatching has been added in FIG. 9 and FIG. 10 respectively indicate the planar shape of the electrode 22 and the electrode 23.

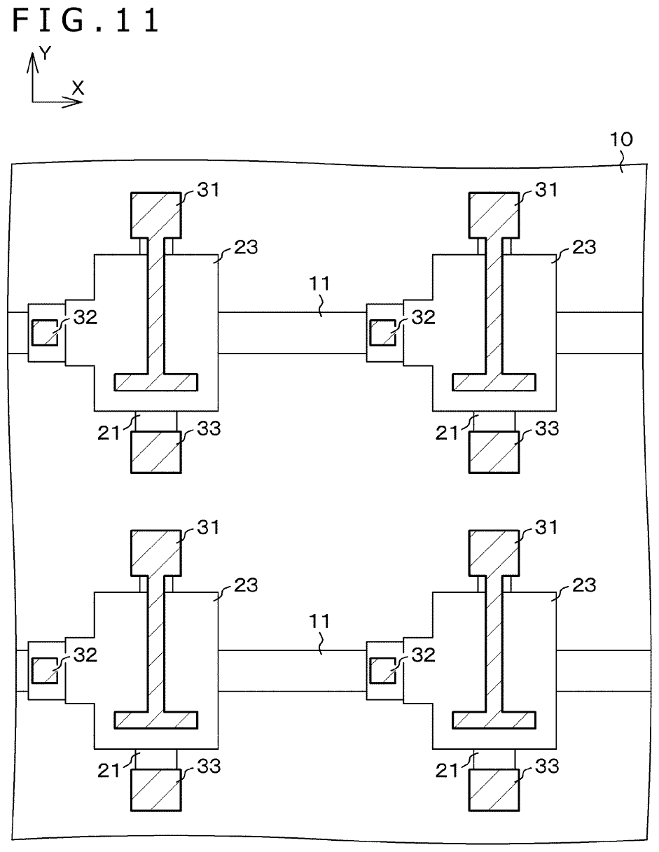

A semiconductor material layer 31 that makes up a thin film transistor is formed on the insulation layer 20 at a portion positioned above the capacitive section CS. Note that a semiconductor material layer 32 illustrated in FIG. 4B and a semiconductor material layer 33 illustrated in FIG. 6B are formed with the purpose of achieving uniformity in a via hole step, and are formed in the same layer as the semiconductor material layer 31. Portions to which hatching has been added FIG. 11 indicate the planar shapes of the semiconductor material layers 31, 32, and 33.

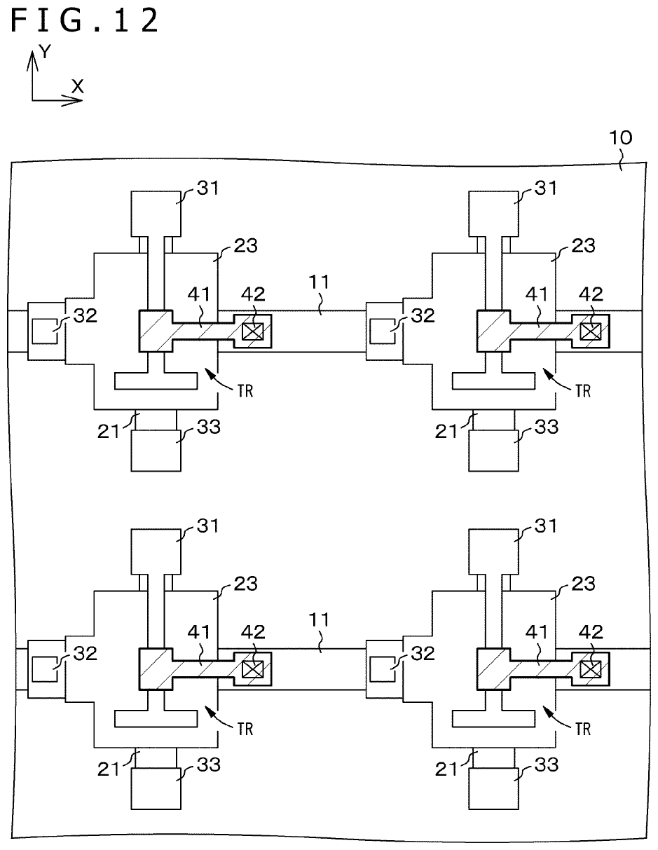

A gate insulating film 34 is formed on the entire surface including on the semiconductor material layers 31, 32, and 33, and a gate electrode 41 is formed on the gate insulating film 34. An opening which exposes the scan line 11 is provided in the gate insulating film 34, the insulation layer 20, and the insulating film 12, and a contact 42 between the gate electrode 41 and the scan line 11 is formed in this portion. As illustrated in FIG. 4B, a thin film transistor TR is configured by the semiconductor material layer 31 and the gate electrode 41. Portions to which hatching has been added in FIG. 12 indicate the planar shape of the gate electrode 41 and the contact. As illustrated in FIG. 12, the gate electrode 41 of a thin film transistor TR is formed extending in the direction in which the scan line 11 extends.

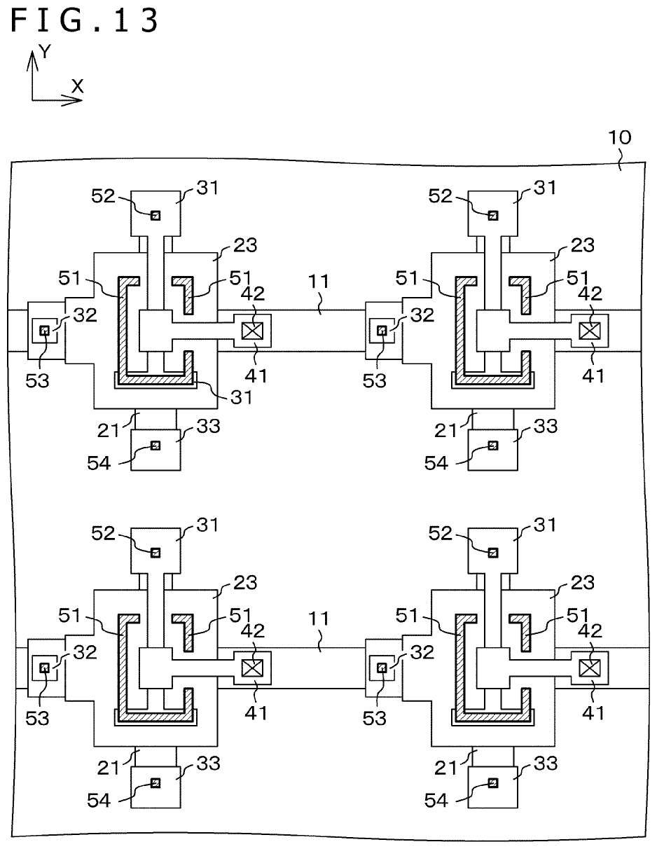

An insulating film 43 is formed on the entire surface including on the gate electrode 41. The perimeter of a thin film transistor TR is surrounded by a wall-shaped horizontal light-blocking film 51 which extends in a normal direction with respect to the support substrate 10 and is in contact with the surface of the electrode 23 which is the uppermost layer of the capacitive section CS. In addition, a contact 53 illustrated in FIG. 4B and contacts 52 and 54 illustrated in FIG. 6B are formed at the same time as a process for forming the horizontal light-blocking film 51. Specifically, after providing an opening at portions where the horizontal light-blocking film 51 and the contacts 52, 53, and 54 are to be formed, a formation process such as embedding an electrically-conductive material having a light-blocking property is performed. Portions to which hatching has been added in FIG. 13 indicate the planar shape of the horizontal light-blocking film 51 and the contacts 52, 53, and 54.

As illustrated in FIG. 6B and FIG. 13, a portion of a horizontal light-blocking film 51 is formed so as to be in contact with the surface of an electrode in the capacitive section CS (more specifically, the surface of the electrode 23) in a state where the semiconductor material layer 31 which makes up a thin film transistor TR is penetrated. In other words, the portion of the horizontal light-blocking film 51 is formed so as to penetrate the other source/drain region of the thin film transistor TR, and reach an electrode surface of the capacitive section CS. Accordingly, the horizontal light-blocking film 51 functions as a common contact with respect to the semiconductor material layer 31 and the capacitive section CS. The pixel voltage is applied to the electrode 23 which is the uppermost layer of the capacitive section CS.

Ordinarily, some amount of a region is necessary in a case of forming a contact. Accordingly, the more the number of contacts increases, the more regions for forming contacts increase, and the aperture ratio decreases as a result. In the present disclosure, because the horizontal light-blocking film 51 which is for light blocking functions as a common contact, it is possible to mitigate a reduction in the aperture ratio.

Next, description is given regarding the contacts 52, 53, and 54 which are formed at the same time as the horizontal light-blocking film 51. As illustrated in FIG. 6B and FIG. 13, the contact 52 is formed, at one end of the semiconductor material layer 31, more specifically in a state where one source/drain region of the thin film transistor is penetrated, so as to reach the electrode 21A.

In addition, the contact 54 is formed, in a state where the semiconductor material layer 33 is penetrated, so as to reach the electrode 21 which makes up the capacitive section CS. The horizontal light-blocking film 51 and the contact 54 are electrically connected via the upper light-blocking film which is described below. Accordingly, the pixel voltage is supplied to the electrode 21 via the contact 54.

In addition, as illustrated in FIG. 4A and FIG. 13, the contact 53 is formed, in a state where the semiconductor material layer 32 is penetrated, so as to reach the electrode 22 which makes up the capacitive section CS. As described below, the common potential V_{com} is supplied to the electrode 22.

Each of the contacts 52, 53, and 54 is formed so as to reach an intended electrode in a state where a semiconductor material layer is penetrated. Accordingly, it is possible to align conditions for when providing openings at portions where the contacts 52, 53, and 54 are to be formed.

An upper light-blocking film 61 positioned above the thin film transistor TR is formed above the insulating film 43 in which the wall-shaped horizontal light-blocking film 51, etc. are embedded. The upper light-blocking film 61 includes an electrically-conductive material having a light-blocking property and is formed so as to be in contact with an end surface of the horizontal light-blocking film 51 and the contact 54. Accordingly, the upper light-blocking film 61 is, via the horizontal light-blocking film 51 and the contact 54, electrically connected to the other source/drain region of the thin film transistor and the electrodes 21 and 23 of the capacitive section CS. A pixel voltage from a signal line is applied to these via the thin film transistor TR which has been set to a conductive state.

Note that an electrode 62 illustrated in FIG. 6B and an electrode 63 illustrated in FIG. 4B have a purpose of functioning as relay electrodes for the contact 52 and the contact 53, respectively, and are formed in the same layer as the upper light-blocking film 61.

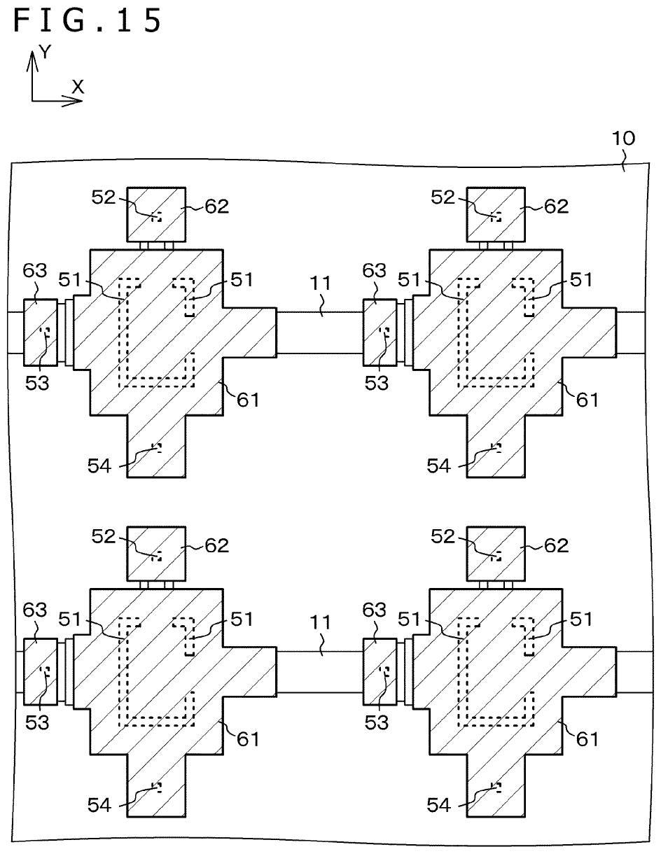

Portions to which hatching has been added in FIG. 15 indicate the planar shapes of the upper light-blocking film 61 and the electrodes 62 and 63. As is clear from comparing FIG. 13 and FIG. 15, the upper light-blocking film 61 is formed so as to cover above each thin film transistor TR, and also cover above a portion of the gate electrode 41 positioned outside the region surrounded by the horizontal light-blocking film 51.

As is clear from the structure described above, the bottom of the thin film transistor TR is covered by an electrode which has a light-blocking property and makes up the capacitive section CS. The perimeter of the thin film transistor TR is surrounded by the wall-shaped horizontal light-blocking film 51, and additionally, the top of the thin film transistor TR is covered by the upper light-blocking film 61. Accordingly, it is possible to effectively shield the thin film transistor TR.

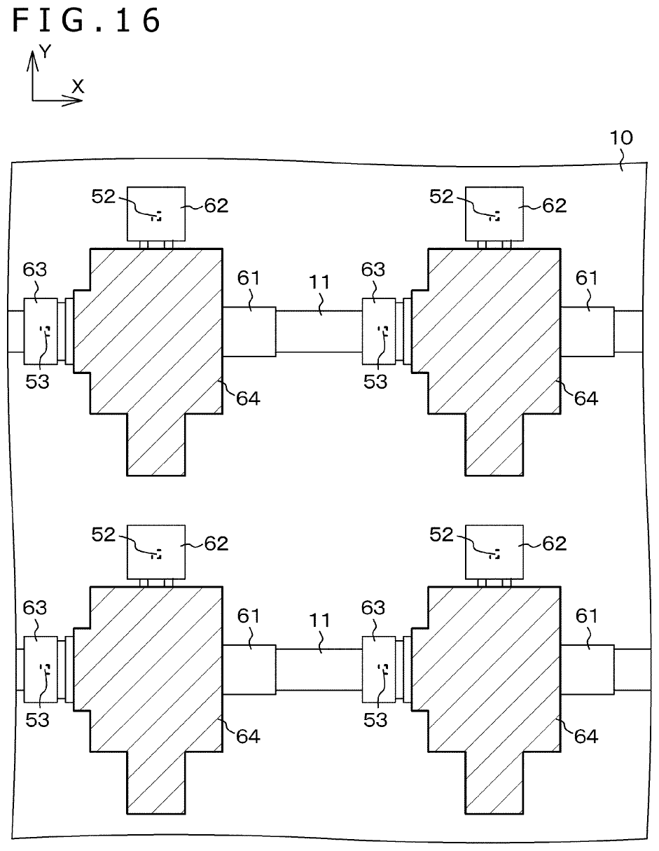

An insulation layer 65 is formed on the entire surface which includes over the upper light-blocking film 61 and the electrodes 62 and 63. Then, a shield electrode 64 embedded in the insulation layer 65 is disposed above the upper light-blocking film 61. Portions to which hatching has been added in FIG. 16 indicate the planar shape of the shield electrode 64.

In addition, a signal line and a common potential line are also formed above the upper light-blocking film 61. A contact 71 which reaches the upper light-blocking film 61, a contact 72 which reaches the electrode 62, a contact 73 which reaches the shield electrode 64, and a contact 74 which reaches the electrode 63 are formed in the insulation layer 65. Then, a signal line 75 (corresponds to the signal line DTL in FIG. 1) extending in the Y direction in the drawing is formed on the insulation layer 65. As illustrated in FIG. 6B, the signal line 75 is, according to the contact 72, connected to one end of the semiconductor material layer 31 via the electrode 62 and the contact 52.

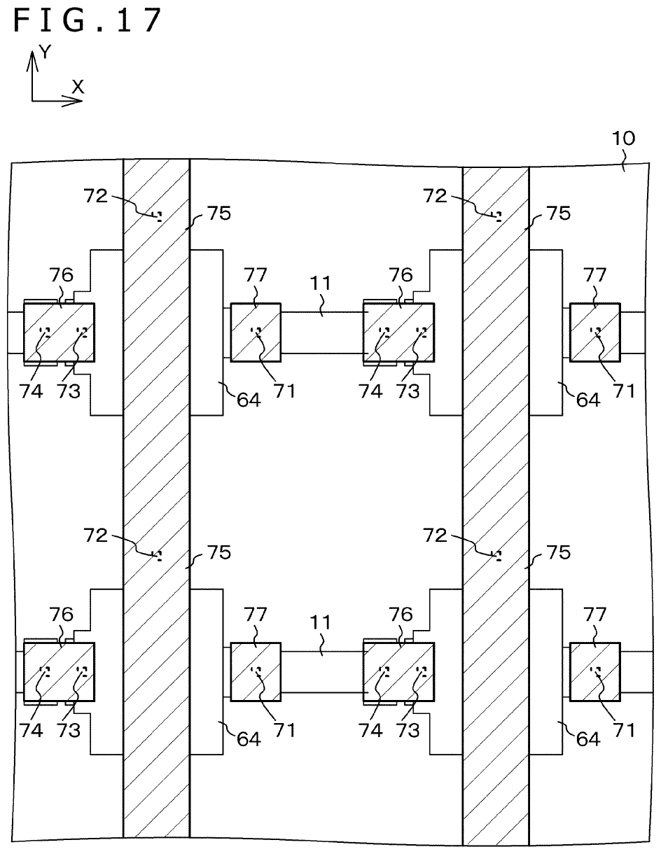

Note that electrodes 76 and 77 illustrated in FIG. 4B have a purpose of functioning as relay electrodes, and are formed in the same layer as the signal line 75. The electrode 76 is disposed at a position in contact with the contacts 73 and 74, and the electrode 77 is disposed at a position that is in contact with the contact 71. Portions to which hatching has been added in FIG. 17 indicate the planar shape of the signal lines 75 and the electrodes 76 and 77.

An insulating film 78 is formed on the entire surface including on the signal line 75 and the electrodes 76 and 77. A contact 81 which reaches the electrode 77 and a contact 82 which reaches the electrode 76 are formed in the insulating film 78. Then, a common potential line 83 which extends in the Y direction in the drawing is formed on the insulating film 78. As illustrated in FIG. 4B, the common potential line 83 is connected to the electrode 22 of the capacitive section CS via the contact 82, the electrode 76, the contact 74, the electrode 63, and the contact 53. Furthermore, the common potential line 83 is connected to the shield electrode 64 via the contact 82, the electrode 76, and the contact 73. Accordingly, the common potential V_{com} is applied to the shield electrode.

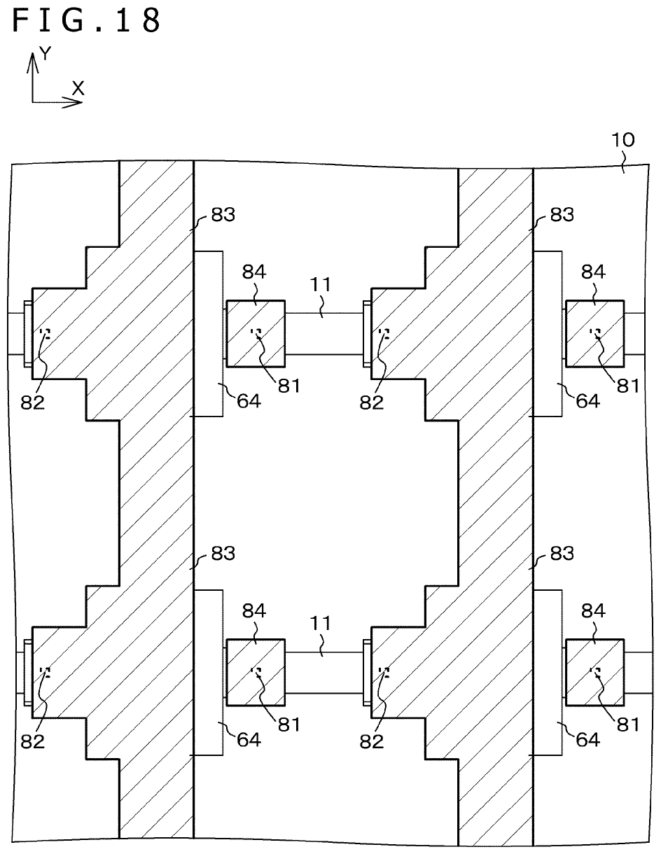

Note that an electrode 84 illustrated in FIG. 4B has a purpose of functioning as relay electrode and is formed in the same layer as the common potential line 83. The electrode 84 is disposed at a position which is in contact with the contact 81. Portions to which hatching has been added in FIG. 18 indicate the planar shape of the common potential line 83 and the electrode 84.

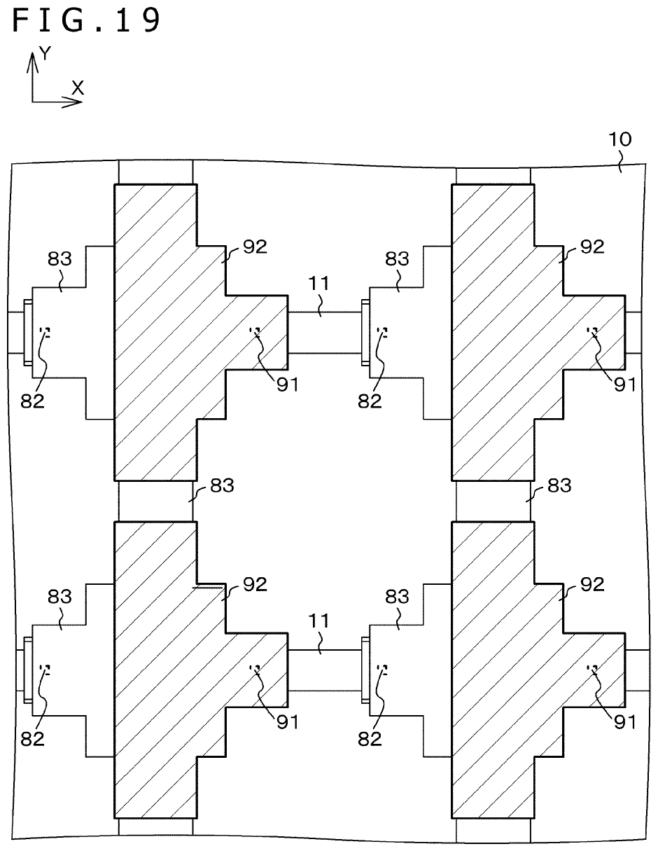

An insulating film 85 is formed on the entire surface including on the common potential line 83 and the electrode 84. A contact 91 which reaches the electrode 84 is formed on the insulating film 85. A relay electrode 92 is formed on the insulating film 85. Portions to which hatching has been added in FIG. 19 indicate the planar shape of the relay electrode 92.

As illustrated in FIG. 4B, the relay electrode 92 is connected to the upper light-blocking film 61 via the contact 91, the electrode 84, the contact 81, the electrode 77, and the contact 71. Because the upper light-blocking film 61 is connected to the capacitive section CS, the pixel voltage held by the capacitive section CS is supplied to the relay electrode 92.

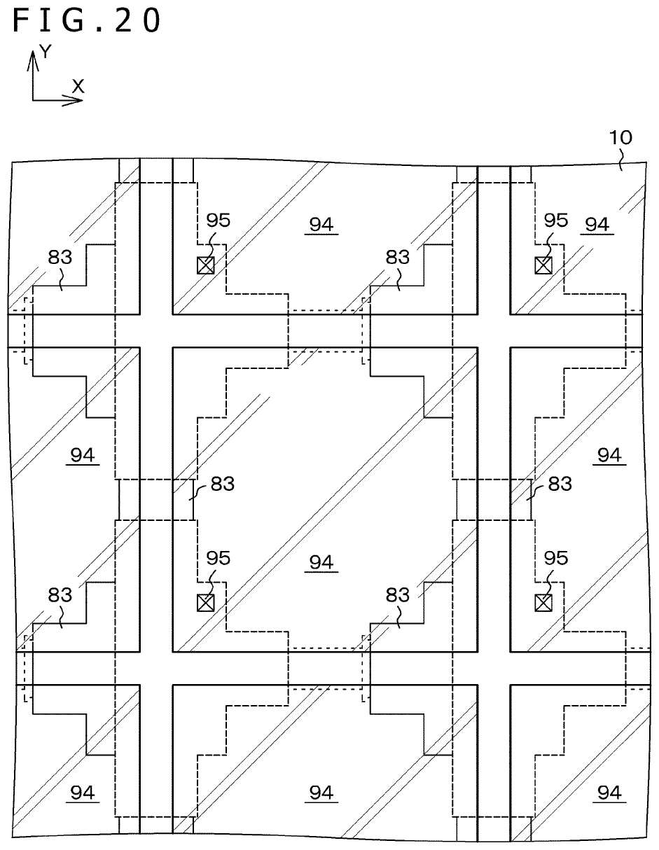

A planarization film 93 is formed on the entire surface including on the relay electrode 92. Pixel electrodes 94 resulting from dividing a transparent conductive film into a two-dimensional matrix shape at a predetermined pitch are formed on the planarization film 93. The reference sign 95 indicates a contact for a pixel electrode 94 and the relay electrode 92. The pixel voltage held by the capacitive section CS is supplied to the pixel electrode 94. Portions to which hatching has been added in FIG. 20 indicate the planar shape of the pixel electrodes 94. Note that, for example, an alignment film, etc. may be formed on the entire surface including on the pixel electrodes 94.

Next, description is given regarding a method of manufacturing a transistor array substrate.

As described above, the transistor array substrate 100 in the liquid crystal display apparatus 1 includes the scan line 11 formed on the support substrate 10, the capacitive section CS formed above the scan line 11, and the thin film transistor TR formed above the capacitive section CS. The perimeter of a thin film transistor TR is surrounded by the wall-shaped horizontal light-blocking film 51 which extends in a normal direction with respect to the support substrate 10 and is in contact with the surface of the electrode 23 which is the uppermost layer of the capacitive section CS The upper light-blocking film 61 is formed above the thin film transistor TR.

The method of manufacturing the transistor array substrate 100 includes a step of, after the scan line 11 is formed on the support substrate 10, forming the capacitive section CS above the scan line 11 and next forming the thin film transistor TR above the capacitive section CS, a step of subsequently forming the wall-shaped horizontal light-blocking film 51, which extends in a normal direction with respect to the support substrate 10 and is in contact with the surface of the electrode 23 which is the uppermost layer of the capacitive section CS, at the perimeter of the thin film transistor TR, and a step of next forming the upper light-blocking film 61 above the thin film transistor.

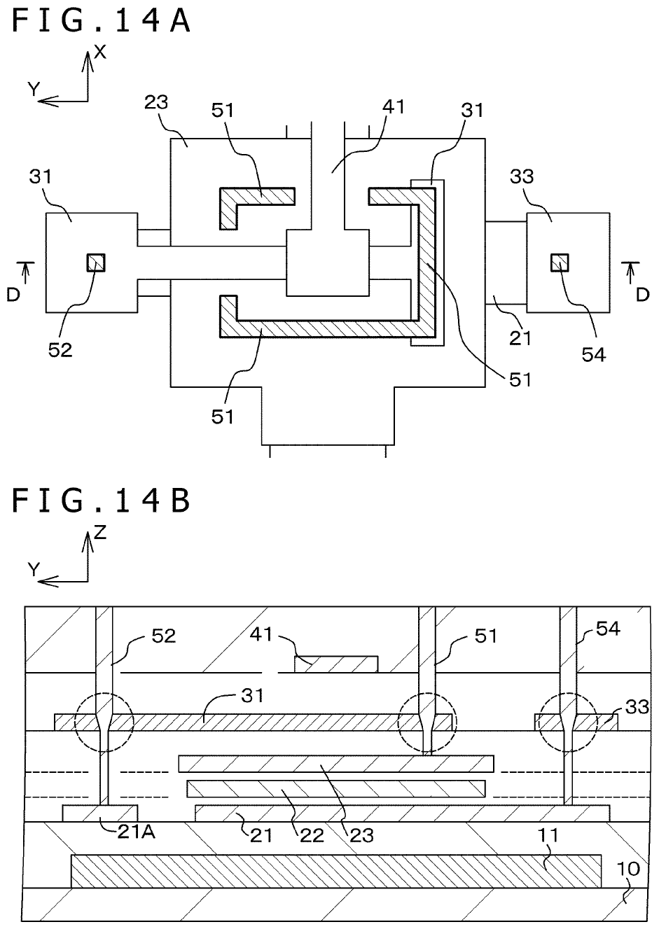

FIG. 7 through FIG. 13 and FIG. 15 through FIG. 20 are schematic partial plan views of a substrate, etc. and are for describing the method of manufacturing the transistor array substrate. Note that, from a perspective of readability, display of insulation layers or insulating films is omitted in these drawings. In addition, FIG. 14A and FIG. 14B are views for describing cross-sectional shapes for a horizontal light-blocking film and contacts which are formed at the same time as the horizontal light-blocking film. With reference to these drawings, description is given in detail below regarding the method of manufacturing the transistor array substrate 100.

[Step-100] (Refer to FIG. 7)

Firstly, the scan lines are formed on the support substrate. Specifically, the support substrate 10 is prepared, and the scan lines 11 are formed thereon according to a well-known film formation method or patterning method. The scan lines 11 include a metal material such as tungsten (W) or Al—Cu, for example.

[Step-110] (Refer to FIG. 8, FIG. 9, and FIG. 10)

Subsequently, the capacitive sections CS are formed above the scan lines 11. The insulating film 12 which includes a silicon oxide, for example, is formed on the entire surface including the scan lines 11, and next the electrodes 21 and 21A which include an electrically conductive material such as silicon (Si) or tungsten (W), for example, are formed (refer to FIG. 8). Subsequently, the electrodes 22 are formed in a state where there is separation from the electrodes 21 according to an insulator (refer to FIG. 9). Next, the electrodes 23 are formed in a state where there is separation from the electrodes 22 according to an insulator (refer to FIG. 10). As a result, the capacitive sections CS are formed above the scan lines 11. Subsequently, a layer including an insulation material is formed on the entire surface including on the electrodes 23, so that the capacitive section CS is embedded in the insulation layer 20.

[Step-120] (Refer to FIG. 11 and FIG. 12)

Next, the thin film transistor TR is formed above the capacitive section CS. By a well-known film formation method or patterning method, the semiconductor material layer 31 which makes up thin film transistors and the semiconductor material layers 32 and 33 are formed on the insulation layer 20 (refer to FIG. 11).

Subsequently, the gate insulating film 34 is formed on the entire surface including on the semiconductor material layers 31, 32, and 33. Next, an opening is provided in the gate insulating film 34 in a portion corresponding to the contact 42. Subsequently, by a well-known film formation method or patterning method, the gate electrode 41 is formed (refer to FIG. 12). As a result, thin film transistors TR are formed above the capacitive sections CS. The insulating film 43 is formed on the entire surface including on the gate electrode 41.

In the steps for forming a thin film transistor TR described above, for example, a process at approximately 1000° C. is necessary.

[Step-130] (Refer to FIG. 13 and FIG. 14)

Next, the wall-shaped horizontal light-blocking film 51, which extends in a normal direction with respect to the support substrate 10 and is in contact with the surface of the electrode which is the uppermost layer of the capacitive section CS, is formed at the perimeter of each thin film transistor TR. Firstly, an opening is formed in the insulating film 43, etc. at a portion corresponding to the horizontal light-blocking film 51. A portion of the opening is formed so as to penetrate the semiconductor material layer 31 and reach the electrode which is the uppermost layer of the capacitive section CS. Note that openings are also formed at portions where the contacts 52, 53, and 54 are to be formed.

Subsequently, the insulating film 43 into which openings have been provided is covered according to an embedding method such as a CVD method using tungsten, for example, and next the tungsten on the insulating film 43 is removed. As a result, the wall-shaped horizontal light-blocking film 51 is formed. In addition, the contacts 52, 53, and 54 are also formed (refer to FIG. 13).

Here, description is given regarding the shape of contacts which penetrate the semiconductor material layer 31, etc. In a portion where the horizontal light-blocking film 51 penetrates the semiconductor material layer 31, a contact surface between the horizontal light-blocking film 51 and the semiconductor material layer 31 has a tapered shape.

FIG. 14A and FIG. 14B are views for describing cross-sectional shapes for a horizontal light-blocking film and contacts which are formed at the same time as the horizontal light-blocking film. FIG. 14A is an enlarged plan view of a portion of the transistor array substrate to which the step illustrated in FIG. 13 has been performed. FIG. 14B is a schematic cross-section view of a portion indicated by D-D in FIG. 14A.

In a case of forming an opening which penetrates the semiconductor material layer 31, dry etching having a selectivity such that an etching speed with respect to the semiconductor material layer 31 is slower than the etching speed with respect to an insulation layer or an insulating film is performed. As a result, the portion which penetrates the semiconductor material layer 31 has a tapered shape as illustrated in FIG. 14B. Accordingly, the contact surface between the horizontal light-blocking film 51 embedded in the opening and the semiconductor material layer 31 has a tapered shape. Note that it is similar for the contacts 52, 53, and 54.

As a result, it is possible to increase the area of contact between the semiconductor material layer 31 and the horizontal light-blocking film 51, and thus it is possible to reduce contact resistance. Note that it is similar for the contact 52. In addition, it is possible to prevent a defect such as not being able to ensure a contact due to the semiconductor material layer 31 being hollowed out.

[Step-140] (Refer to FIG. 15)

Subsequently, the upper light-blocking film 61 is formed above each thin film transistor TR. By a well-known film formation method or patterning method, the upper light-blocking film 61 including an electrically-conductive material having a light-blocking property such as tungsten silicide, for example, is formed, and the electrodes 62 and 63 are also formed (refer to FIG. 15). Because ends of the horizontal light-blocking film 51 are exposed in the surface of the insulating film 43, the upper light-blocking film 61 is in contact with the ends of the horizontal light-blocking film 51.

[Step-150] (Refer to FIG. 16)

Next, the shield electrode 64 is formed above each upper light-blocking film 61. A lower layer portion of the insulation layer 65 is formed over the entire surface including on the upper light-blocking film 61. Subsequently, by a well-known film formation method or patterning method, the shield electrode 64 is formed on the lower layer portion (refer to FIG. 16). Next, the upper layer portion of the insulation layer 65 is formed on the entire surface.

[Step-160] (Refer to FIG. 17)

Subsequently, signal lines 75 are formed on the insulation layer 65. Firstly, after the contacts 71, 72, 73, and 74 are formed in the insulation layer 65, by a well-known film formation method or patterning method, the signal lines 75 are formed, and the electrodes 76 and 77 are also formed (refer to FIG. 17). Next, the insulating film 78 is formed on the entire surface.

[Step-170] (Refer to FIG. 18)

Subsequently, common potential lines 83 are formed on the insulating film 78. Firstly, after the contacts 81 and 82 are formed in the insulating film 78, by a well-known film formation method or patterning method, the common potential lines 83 are formed, and the electrodes 84 are also formed (refer to FIG. 18). Next, the insulating film 85 is formed on the entire surface.

[Step-180] (Refer to FIG. 19)

Subsequently, relay electrodes 92 are formed on the insulating film 85. Firstly, after contacts 91 are formed in the insulating film 85, by a well-known film formation method or patterning method, the relay electrodes 92 are formed (refer to FIG. 19). Next, the planarization film 93 is formed on the entire surface.

[Step-190] (Refer to FIG. 20)

Subsequently, pixel electrodes 94 are formed on the planarization film 93. Firstly, after openings are formed at portions corresponding to contacts 95 in the planarization film 93, a transparent electrically conductive material layer is formed on the entire surface. By dividing the transparent electrically conductive material layer according to a well-known patterning method, it is possible to obtain the pixel electrodes (refer to FIG. 20).

Description has been given above regarding the method of manufacturing the transistor array substrate 100. Note that, in a case of manufacturing the liquid crystal display apparatus 1, it is sufficient if, after an alignment film, etc. is formed on the transistor array substrate 100, a step of, for example, causing the transistor array substrate 100 to face a counter substrate in a state where a liquid crystal material layer is sandwiched therebetween and the perimeter thereof is sealed is performed.

In steps for manufacturing a transistor array substrate described above, a process at approximately 1000° C. is necessary to form a semiconductor material layer which makes up a thin film transistor, but a series of processes subsequent thereto are performed at approximately 400° C. In a case where a light-blocking film is formed using, for example, tungsten silicide, the light-blocking property is reduced to substantially a fraction thereof upon being exposed to a temperature such as approximately 1000° C. In the steps described above, because the horizontal light-blocking film or the upper light-blocking film are not exposed to a temperature such as approximately 1000° C., it is possible to keep the light-blocking property of the light-blocking film itself.

### First Modification Example

In a case where it is not possible to set the insulation layer between a capacitive section and a semiconductor material layer to be sufficiently thick, a characteristic such as a threshold voltage Vth for a thin film transistor TR is changed according to a back-gate effect. A first modification example is an example which can be applied to a case such as that described above, and differs in also adding a gate shield electrode to a gate electrode.

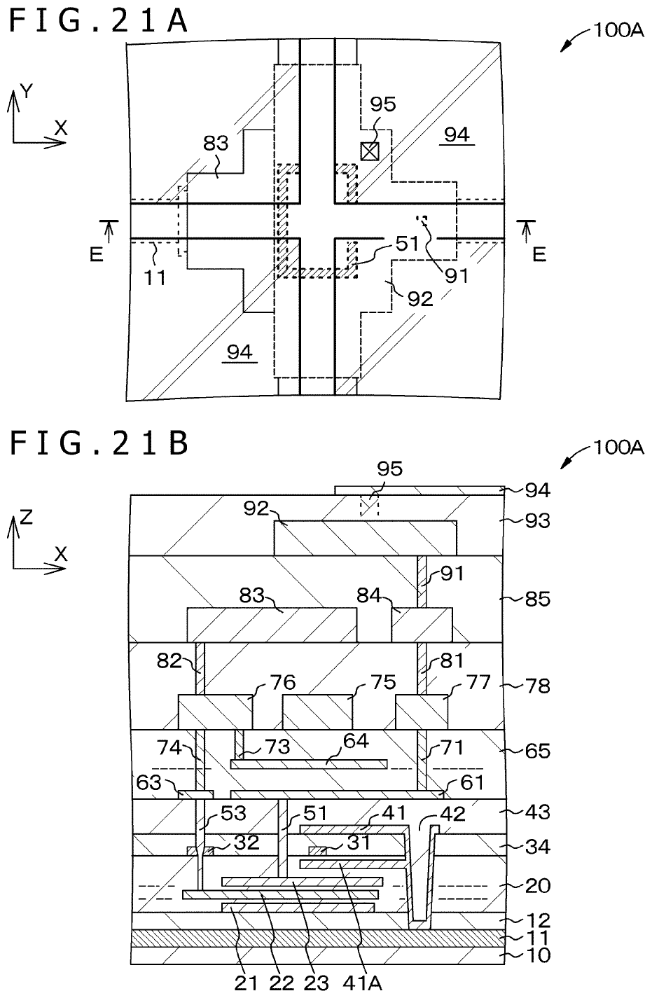

FIG. 21A and FIG. 21B are views for describing a cross-sectional structure in a transistor array substrate used in a liquid crystal display apparatus, according to the first modification example. FIG. 21A is a schematic plan view which includes a portion between pixel electrodes in the transistor array substrate. FIG. 21B is a schematic cross-section view of a portion indicated by E-E in FIG. 21A.

In the transistor array substrate 100 having the connection relation illustrated in FIG. 4 through FIG. 6, the electrode which is the uppermost layer of a capacitive section holds the pixel voltage. For example, consideration is given to a case in which, using a n-channel thin film transistor TR, the thin film transistor TR is set to a non-conducting state with the voltage at the gate electrode as a low level after a high-level signal is written as the pixel voltage. In such a case, the electrode which is the uppermost layer of the capacitive section holds the high level and thus acts as a back-gate. Accordingly, it is not possible to sufficiently maintain the non-conducting state for the thin film transistor TR even if the voltage of the gate electrode is set to the low level, and a leakage current increases.

Accordingly, in a transistor array substrate 100A according to the modification example, a thin film transistor TR is further provided with a gate shield electrode 41A formed on a surface side of the semiconductor material layer 31, which makes up the thin film transistor TR, opposite to the surface of the semiconductor material layer 31 on the gate electrode 41 side. In other words, configuration is taken such that the semiconductor material layer 31 is sandwiched by the gate electrode 41 and the gate shield electrode 41A. The planar shape of the gate shield electrode 41A is substantially the same as the shape of the gate electrode 41 illustrated in FIG. 12. As a result, it is possible to reduce the effect of the back-gate.

### Second Modification Example

In the transistor array substrate 100, the capacitive section CS is configured from three electrodes, and the uppermost electrode holds the pixel voltage. However, the voltage held by the uppermost electrode in the capacitive section CS is not limited to the pixel voltage. A second modification example is one in which can be applied to a case such as that described above, and mainly differs in that a common potential is applied to the uppermost electrode in the capacitive section CS.

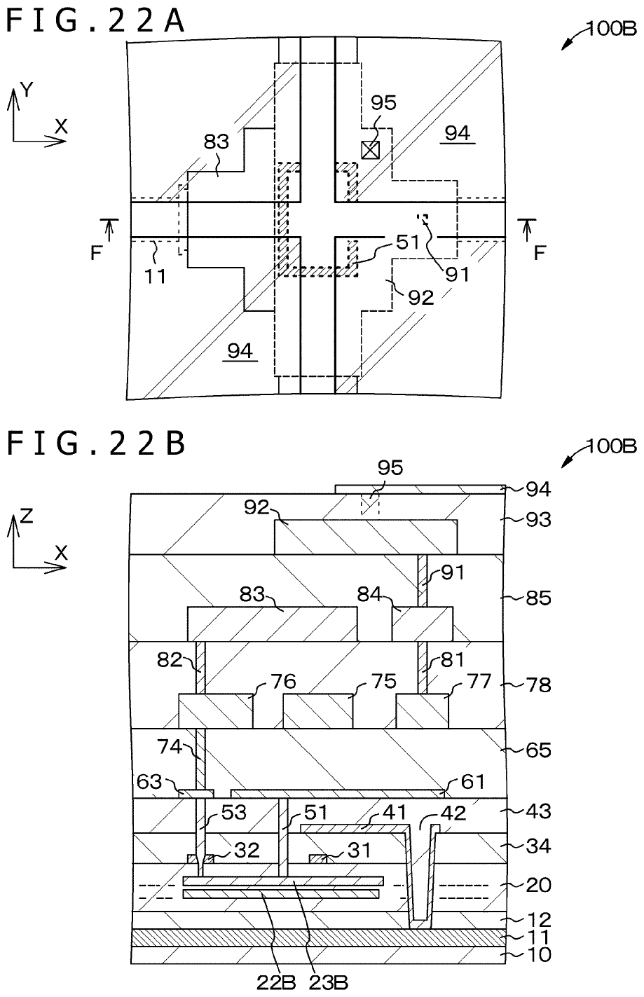

FIG. 22A and FIG. 22B are views for describing a cross-sectional structure in a transistor array substrate used in a liquid crystal display apparatus, according to the second modification example. FIG. 22A is a schematic plan view which includes a portion between pixel electrodes in the transistor array substrate. FIG. 22B is a schematic cross-section view of a portion indicated by F-F in FIG. 22A.

In a transistor array substrate 100B, a capacitive section CS is configured from electrodes 22B and 23B. The uppermost electrode 23B is connected to the common potential line 83 via the contact 53, the electrode 63, the contact 74, the electrode 76, and the contact 82. Accordingly, the common potential V_{com} is supplied to the electrode 23B and the horizontal light-blocking film 51 and the upper light-blocking film 61 which are electrically connected to the electrode 23B. In contrast, the electrode 22B is connected to the electrode 77 and the other source/drain region of the thin film transistor TR, via a contact, for example, which is not illustrated.

Because the common potential V_{com} is supplied to the upper light-blocking film 61, the upper light-blocking film 61 acts as a shield for the thin film transistor TR. Accordingly, it is possible to omit the shield electrode 64 illustrated in FIG. 4 through FIG. 6. In addition, if the common potential V_{com} is a stable potential, the gate shield electrode described in the first modification example is unnecessary. Accordingly, by virtue of the second modification example, it is possible to, for example, reduce the number of processes.

In a transistor array substrate according to the present disclosure, because the contact with the capacitive section is formed by penetrating a semiconductor material layer, it is possible to reduce the number of contacts, and reduce a region occupied by a pixel circuit. As a result, it is possible to reduce a tendency for the aperture ratio to decrease in conjunction with miniaturization. Furthermore, because it is possible to provide a tapered surface at a portion of a semiconductor material layer when forming a contact hole, it is possible to improve electrical connectivity with the semiconductor material layer.

In addition, in a transistor array substrate according to the present disclosure, the thin film transistor is covered by the electrodes of the capacitive section in addition to the horizontal light-blocking film and the upper light-blocking film. Accordingly, it is possible to more effectively shield the thin film transistor while reducing the tendency for the aperture ratio to decrease.

In addition, in the transistor array substrate according to the present disclosure, it is possible to form the horizontal light-blocking film and the upper light-blocking film after a step of forming the thin film transistor which requires a high-temperature process. Accordingly, because the horizontal light-blocking film and the upper light-blocking film are formed with a comparatively low temperature thermal history, the advantage that it is possible to avoid a decrease in a light-blocking property due to exposure to a high-temperature process is also provided.

In a liquid crystal display apparatus according to the present disclosure, leaks from transistors are reduced, and it is possible to reduce a tendency for the aperture ratio to decrease in conjunction with miniaturization. As a result, it is possible to display a bright image with high definition.

### [Description of Electric Equipment]

The liquid crystal display apparatus according to the present disclosure described above can be used as a display unit (display apparatus) for electronic equipment of any field to display, as an image or a video, a video signal inputted to the electronic equipment or a video signal generated within the electronic equipment. As an example, usage is possible as a display unit such as for a television set, a digital still camera, a laptop personal computer, a portable terminal apparatus such as a mobile telephone, a video camera, or a head-mounted display, for example.

A liquid crystal display apparatus according to the present disclosure includes something with a module shape having a sealed configuration. As an example, a display module formed by a counter section made of, for example, a transparent glass material being pasted to a pixel array section corresponds. Note that, for example, a circuit section or a flexible printed circuit (FPC) for input and output of a signal, etc. from an external unit to the pixel array section may be provided in the display module. A projection-type display apparatus, a digital still camera, and a head-mounted display are exemplified below as specific examples of electric equipment which use a liquid crystal display apparatus according to the present disclosure. However, the specific examples exemplified here are merely examples, and there is no limitation thereto.

### Specific Example 1

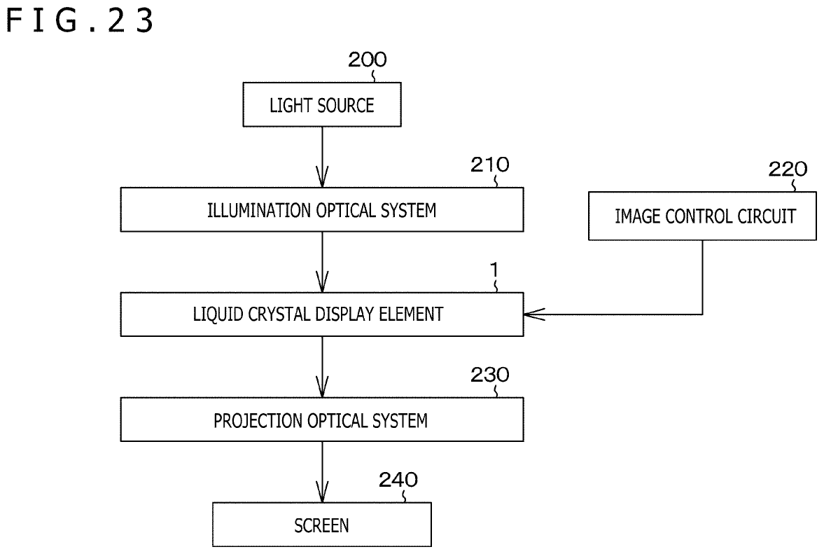

FIG. 23 is a conceptual diagram of a projection-type display apparatus which uses a liquid crystal display apparatus according to the present disclosure. The projection-type display apparatus is configured from, for example, a light source 200, an illumination optical system 210, the liquid crystal display apparatus 1, an image control circuit 220 which drives the liquid crystal display apparatus, a projection optical system 230, and a screen 240. The light source 200 can be configured from various lamps such as xenon lamps, or a semiconductor light emitting element such as a light emitting diode, for example. The illumination optical system 210 is used to guide light from the light source 200 to the liquid crystal display apparatus 1 and is configured from an optical element such as a prism or a dichroic mirror. The liquid crystal display apparatus 1 acts as a light valve, and an image is projected onto the screen 240 via the projection optical system 230.

### Specific Example 2

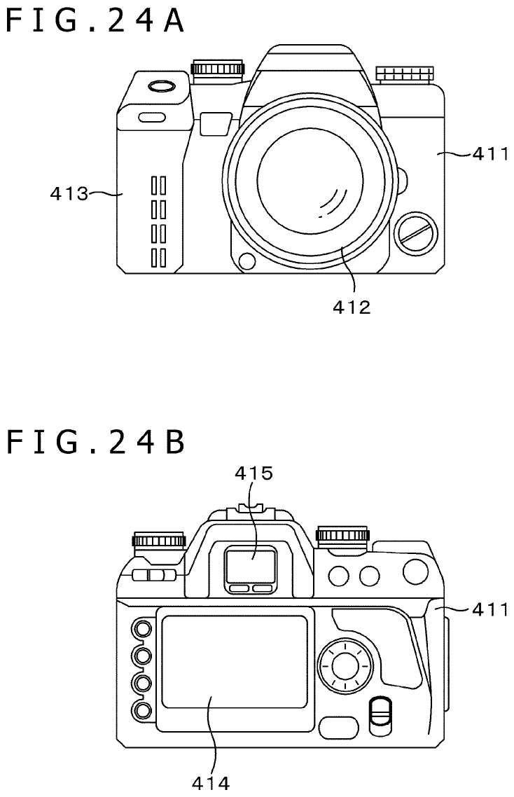

FIG. 24 depicts external views of a lens interchangeable single lens reflex type digital still camera, with FIG. 24A illustrating a front view thereof, and FIG. 24B illustrating a rear view thereof. The lens interchangeable single lens reflex type digital still camera, for example, has an interchangeable image capturing lens unit (interchangeable lens) 412 on a front right side of a camera main body section (camera body) 411, and has a grip section 413 on the front left side for a photographer to grip.

Then, a monitor 414 is provided in the substantial center on the rear surface of the camera main body section 411. A viewfinder (eyepiece window) 415 is provided above the monitor 414. By looking through the viewfinder 415, the photographer can determine the composition by visually recognizing a light image of a subject guided from the image capturing lens unit 412.

In a lens interchangeable single lens reflex type digital still camera with the configuration described above, it is possible to use a liquid crystal display apparatus according to the present disclosure as the viewfinder 415 thereof. In other words, a lens interchangeable single lens reflex type digital still camera according to the present example is manufactured by using a liquid crystal display apparatus according to the present disclosure as the viewfinder 415 thereof.

### Specific Example 3

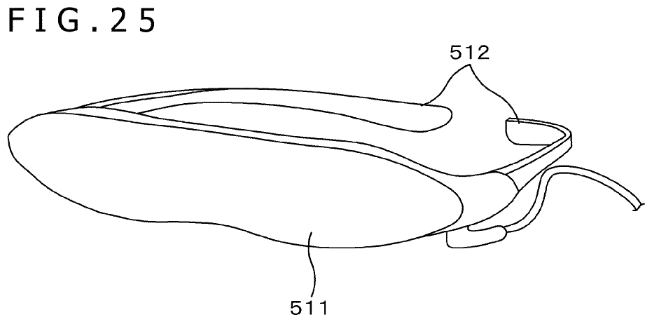

FIG. 25 is an external view of a head-mounted display. The head-mounted display, for example, has, on both sides of a glasses-shaped display unit 511, ear hooking sections 512 for mounting to the head of a user. In the head-mounted display, it is possible to use a liquid crystal display apparatus according to the present disclosure as the display unit 511 thereof. In other words, the head-mounted display according to the present example is manufactured by using a liquid crystal display apparatus according to the present disclosure as the display unit 511 thereof.

### Specific Example 4

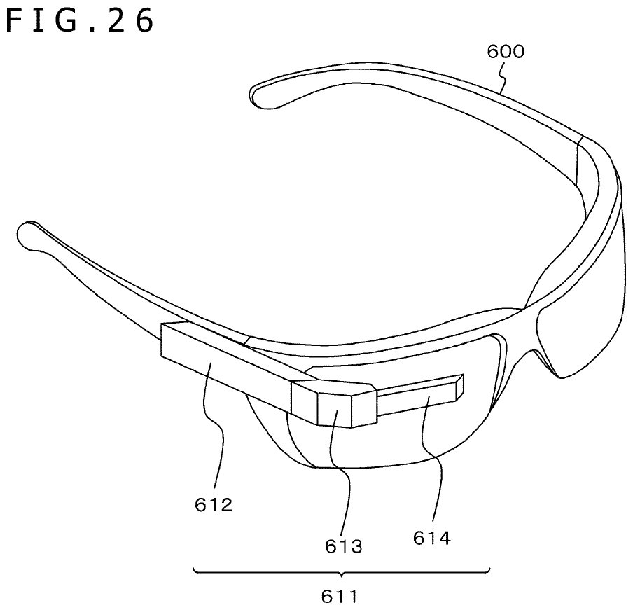

FIG. 26 is an external view of a see-through head-mounted display. A see-through head-mounted display 611 is configured from a main body section 612, an arm 613, and a lens barrel 614.

The main body section 612 is connected to the arm 613 and glasses 600. Specifically, an end in a long side direction of the main body section 612 is joined to the arm 613, and one side of side surfaces of the main body section 612 is connected to the glasses 600 via a connection member. Note that the main body section 612 may be directly mounted to the head of a human body.

The main body section 612 incorporates a display unit or a control substrate for controlling operation of the see-through head-mounted display 611. The arm 613 connects the main body section 612 and the lens barrel 614, and supports the lens barrel 614. Specifically, the arm 613 is joined to each of an end of the main body section 612 and an end of the lens barrel 614, and fixes the lens barrel 614. In addition, the arm 613 incorporates a signal line for communicating data pertaining to an image to be provided to the lens barrel 614 from the main body section 612.

The lens barrel 614 projects image light provided, via the arm 613, from the main body section 612 through an eyepiece lens toward an eye of a user who mounts the see-through head-mounted display 611. In the see-through head-mounted display 611, it is possible to use a liquid crystal display apparatus according to the present disclosure for a display unit of the main body section 612.

### OTHER

Note that the technology of the present disclosure can also have the following configurations.

### [A1]

A transistor array substrate including:

a scan line formed on a support substrate;

a capacitive section formed above the scan line; and

a thin film transistor formed above the capacitive section, in which

a perimeter of the thin film transistor is surrounded by a wall-shaped horizontal light-blocking film that extends in a normal direction with respect to the support substrate and is in contact with a surface of an electrode that is an uppermost layer of the capacitive section, and

an upper light-blocking film is formed above the thin film transistor.

### [A2]

The transistor array substrate according to [A1] described above, in which

the horizontal light-blocking film and the upper light-blocking film include an electrically-conductive material having a light-blocking property.

### [A3]

The transistor array substrate according to [A2] described above, in which

a portion of the horizontal light-blocking film is formed so as to be in contact with an electrode surface of the capacitive section in a state where a semiconductor material layer that makes up the thin film transistor is penetrated.

### [A4]

The transistor array substrate according to [A2] described above, in which,

in a portion where the horizontal light-blocking film penetrates a semiconductor material layer, a contact surface between the horizontal light-blocking film and the semiconductor material layer has a tapered shape.

### [A5]

The transistor array substrate according to any of [A1] through [A4] described above, in which

a gate electrode of the thin film transistor is formed extending in a direction in which the scan line extends, and

the upper light-blocking film is formed so as to cover above the thin film transistor, and also cover above a portion of the gate electrode positioned outside a region surrounded by the horizontal light-blocking film.

### [A6]

The transistor array substrate according to [A5] described above, in which

the thin film transistor is further provided with a gate shield electrode formed on a surface side of a semiconductor material layer that makes up the thin film transistor, the surface side being opposite to a surface of the semiconductor material layer on the gate electrode side.

### [A7]

The transistor array substrate according to any of [A1] through [A6] described above, in which

an electrode that makes up the capacitive section includes an electrically-conductive material having a light-blocking property.

### [A8]

The transistor array substrate according to any of [A1] through [A7] described above, in which

a shield electrode is formed above the upper light-blocking film.

### [A9]

The transistor array substrate according to [A8] described above, in which

a common potential is applied to the shield electrode.

### [A10]

The transistor array substrate according to any of [A1] through [A9] described above, in which

a pixel voltage is applied to the electrode that is the uppermost layer of the capacitive section.

### [A11]

The transistor array substrate according to any of [A1] through [A10] described above, in which a common potential is applied to the electrode that is the uppermost layer of the capacitive section.

### [A12]

The transistor array substrate according to any of [A1] through [A11] described above, in which

a common potential line and a signal line are further formed above the upper light-blocking film.

### [A13]

The transistor array substrate according to any of [A1] through [A12] described above, further including:

a pixel electrode to which a pixel voltage held by the capacitive section is applied.

### [B1]

A method of manufacturing a transistor array substrate, including:

a step of, after a scan line is formed on a support substrate, forming a capacitive section above the scan line and next forming a thin film transistor above the capacitive section;

a step of subsequently forming a wall-shaped horizontal light-blocking film that extends in a normal direction with respect to the support substrate and is in contact with an electrode that is an uppermost layer of the capacitive section, at a perimeter of the thin film transistor; and

a step of next forming an upper light-blocking film above the thin film transistor.

### [B2]

The method of manufacturing a transistor array substrate according to [B1] described above, in which the horizontal light-blocking film and the upper light-blocking film include an electrically-conductive material having a light-blocking property.

### [B3]

The method of manufacturing a transistor array substrate according to [B2] described above, in which

a portion of the horizontal light-blocking film is formed so as to be in contact with an electrode surface of the capacitive section in a state where a semiconductor material layer that makes up the thin film transistor is penetrated.

### [B4]

The method of manufacturing a transistor array substrate according to [B2] described above, in which,

in a portion where the horizontal light-blocking film penetrates a semiconductor material layer, a contact surface between the horizontal light-blocking film and the semiconductor material layer has a tapered shape.

### [B5]

The method of manufacturing a transistor array substrate according to any of [B1] through [B4] described above, in which

a gate electrode of the thin film transistor is formed extending in a direction in which the scan line extends, and

the upper light-blocking film is formed so as to cover above the thin film transistor, and also cover above a portion of the gate electrode positioned outside a region surrounded by the horizontal light-blocking film.

### [B6]

The method of manufacturing a transistor array substrate according to [B5] described above, in which

the thin film transistor is further provided with a gate shield electrode formed on a surface side of a semiconductor material layer that makes up the thin film transistor, the surface side being opposite to a surface of the semiconductor material layer on the gate electrode side.

### [B7]

The method of manufacturing a transistor array substrate according to any of [B1] through [B6] described above, in which

an electrode that makes up the capacitive section includes an electrically-conductive material having a light-blocking property.

### [B8]

The method of manufacturing a transistor array substrate according to any of [B1] through [B7] described above, in which

a shield electrode is formed above the upper light-blocking film.

### [B9]

The method of manufacturing a transistor array substrate according to [B8] described above, in which

a common potential is applied to the shield electrode.

[B10]

The method of manufacturing a transistor array substrate according to any of [B1] through [B9] described above, in which

a pixel voltage is applied to the electrode that is the uppermost layer of the capacitive section.

### [B11]

The method of manufacturing a transistor array substrate according to any of [B1] through [B10] described above, in which

a common potential is applied to the electrode that is the uppermost layer of the capacitive section.

### [B12]

The method of manufacturing a transistor array substrate according to any of [B1] through [B11] described above, in which

a common potential line and a signal line are further formed above the upper light-blocking film.

### [B13]

The method of manufacturing a transistor array substrate according to any of [B1] through [B12] described above, in which

a pixel electrode to which a pixel voltage held by the capacitive section is applied.

is further included.

### [C1]

A liquid crystal display apparatus including:

a transistor array substrate;

a counter substrate disposed so as to oppose the transistor array substrate; and

a liquid crystal material layer enclosed between the transistor array substrate and the counter substrate, in which

the transistor array substrate includes
a scan line formed on a support substrate,
a capacitive section formed above the scan line, and
a thin film transistor formed above the capacitive section,

a perimeter of the thin film transistor is surrounded by a wall-shaped horizontal light-blocking film that extends in a normal direction with respect to the support substrate and is in contact with an electrode that is an uppermost layer of the capacitive section, and

an upper light-blocking film is formed above the thin film transistor.

### [C2]

The liquid crystal display apparatus according to [C1] described above, in which

the horizontal light-blocking film and the upper light-blocking film include an electrically-conductive material having a light-blocking property.

### [C3]

The liquid crystal display apparatus according to [C2] described above, in which

a portion of the horizontal light-blocking film is formed so as to be in contact with an electrode surface of the capacitive section in a state where a semiconductor material layer that makes up the thin film transistor is penetrated.

### [C4]

The liquid crystal display apparatus according to [C2] described above, in which,

in a portion where the horizontal light-blocking film penetrates a semiconductor material layer, a contact surface between the horizontal light-blocking film and the semiconductor material layer has a tapered shape.

### [C5]

The liquid crystal display apparatus according to any of [C1] through [C4] described above, in which

a gate electrode of the thin film transistor is formed extending in a direction in which the scan line extends, and

the upper light-blocking film is formed so as to cover above the thin film transistor, and also cover above a portion of the gate electrode positioned outside a region surrounded by the horizontal light-blocking film.

### [C6]

The liquid crystal display apparatus according to [C5] described above, in which

the thin film transistor is further provided with a gate shield electrode formed on a surface side of a semiconductor material layer that makes up the thin film transistor, the surface side being opposite to a surface of the semiconductor material layer on the gate electrode side.

### [C7]

The liquid crystal display apparatus according to any of [C1] through [C6] described above, in which

an electrode that makes up the capacitive section includes an electrically-conductive material having a light-blocking property.

### [C8]

The liquid crystal display apparatus according to any of [C1] through [C7] described above, in which

a shield electrode is formed above the upper light-blocking film.

### [C9]

The liquid crystal display apparatus according to [C8] described above, in which

a common potential is applied to the shield electrode.

### [C10]

The liquid crystal display apparatus according to any of [C1] through [C9] described above, in which

a pixel voltage is applied to the electrode that is the uppermost layer of the capacitive section.

### [C11]

The liquid crystal display apparatus according to any of [C1] through [C10] described above, in which

a common potential is applied to the electrode that is the uppermost layer of the capacitive section.

### [C12]

The liquid crystal display apparatus according to any of [C1] through [C11] described above, in which

a common potential line and a signal line are further formed above the upper light-blocking film.

### [C13]

The liquid crystal display apparatus according to any of

[C1] through [C12] described above, further including:

a pixel electrode to which a pixel voltage held by the capacitive section is applied.

### [D1]

Electronic equipment including:

a liquid crystal display apparatus including
a transistor array substrate,
a counter substrate disposed so as to oppose the transistor array substrate, and
a liquid crystal material layer enclosed between the transistor array substrate and the counter substrate, in which
the transistor array substrate includes
   a scan line formed on a support substrate,
   a capacitive section formed above the scan line, and
   a thin film transistor formed above the capacitive section,
a perimeter of the thin film transistor is surrounded by a wall-shaped horizontal light-blocking film that extends in a normal direction with respect to the support substrate and is in contact with an electrode that is an uppermost layer of the capacitive section, and
an upper light-blocking film is formed above the thin film transistor.

### [D2]

The electronic equipment according to [D1] described above, in which

the horizontal light-blocking film and the upper light-blocking film include an electrically-conductive material having a light-blocking property.

### [D3]

The electronic equipment according to [D2] described above, in which

a portion of the horizontal light-blocking film is formed so as to be in contact with an electrode surface of the capacitive section in a state where a semiconductor material layer that makes up the thin film transistor is penetrated.

### [D4]

The electronic equipment according to [D2] described above, in which,

in a portion where the horizontal light-blocking film penetrates a semiconductor material layer, a contact surface between the horizontal light-blocking film and the semiconductor material layer has a tapered shape.

### [D5]

The electronic equipment according to any of [D1] through [D4] described above, in which

a gate electrode of the thin film transistor is formed extending in a direction in which the scan line extends, and

the upper light-blocking film is formed so as to cover above the thin film transistor, and also cover above a portion of the gate electrode positioned outside a region surrounded by the horizontal light-blocking film.

### [D6]

The electronic equipment according to [D5] described above, in which

the thin film transistor is further provided with a gate shield electrode formed on a surface side of a semiconductor material layer that makes up the thin film transistor, the surface side being opposite to a surface of the semiconductor material layer on the gate electrode side.

### [D7]

The electronic equipment according to any of [D1] through [D6] described above, in which

an electrode that makes up the capacitive section includes an electrically-conductive material having a light-blocking property.

### [D8]

The electronic equipment according to any of [D1] through [D7] described above, in which

a shield electrode is formed above the upper light-blocking film.

### [D9]

The electronic equipment according to [D8] described above, in which

a common potential is applied to the shield electrode.

### [D10]

The electronic equipment according to any of [D1] through [D9] described above, in which

a pixel voltage is applied to the electrode that is the uppermost layer of the capacitive section.

### [D11]

The electronic equipment according to any of [D1] through [D10] described above, in which

a common potential is applied to the electrode that is the uppermost layer of the capacitive section.

### [D12]

The electronic equipment according to any of [D1] through [D11] described above, in which

a common potential line and a signal line are further formed above the upper light-blocking film.

### [D13]

The electronic equipment according to any of [D1] through [D12] described above, further including:

a pixel electrode to which a pixel voltage held by the capacitive section is applied.

### REFERENCE SIGNS LIST

1: Liquid crystal display apparatus
10: Support substrate
11: Scan line
12: Insulating film
20: Insulation layer
21, 22, 23, 22B, 23B: Electrode configuring capacitive section
31, 32, 33: Semiconductor material layer
34: Gate insulating film
41: Gate electrode
42: Contact for gate electrode
41A: Back-gate electrode
43: Insulating film
51: Horizontal light-blocking film
52, 53, 54: Contact
61: Upper light-blocking film
62, 63: Electrode
64: Shield electrode
65: Insulation layer
71, 72, 73, 74: Contact
75: Signal line
76, 77: Electrode
78: Insulating film
81, 82: Contact
83: Common potential line
84: Electrode
85: Insulating film
91: Contact
92: Relay electrode
93: Planarization film
94: Pixel electrode
95: Contact for pixel electrode
100, 100A, 100B: Transistor array substrate
101: Horizontal drive circuit
102: Vertical drive circuit
110: Liquid crystal material layer
111: Seal part
120: Opposing substrate
200: Light source
210: Illumination optical system
220: Image control circuit
230: Projection optical system
240: Screen
411: Camera main body section
412: Image capturing lens unit
413: Grip section
414: Monitor
415: Viewfinder
511: Glasses-shaped display unit
512: Ear hooking section
600: Glasses
611: See-through head-mounted display
612: Main body section
613: Arm
614: Lens barrel

1. A transistor array substrate comprising:
a scan line formed on a support substrate;
a capacitive section formed above the scan line; and
a thin film transistor formed above the capacitive section, wherein
a perimeter of the thin film transistor is surrounded by a wall-shaped horizontal light-blocking film that extends in a normal direction with respect to the support substrate and is in contact with a surface of an electrode that is an uppermost layer of the capacitive section, and
an upper light-blocking film is formed above the thin film transistor.

2. The transistor array substrate according to claim 1, wherein
the horizontal light-blocking film and the upper light-blocking film include an electrically-conductive material having a light-blocking property.

3. The transistor array substrate according to claim 2, wherein
a portion of the horizontal light-blocking film is formed so as to be in contact with an electrode surface of the capacitive section in a state where a semiconductor material layer that makes up the thin film transistor is penetrated.

4. The transistor array substrate according to claim 2, wherein,
in a portion where the horizontal light-blocking film penetrates a semiconductor material layer, a contact surface between the horizontal light-blocking film and the semiconductor material layer has a tapered shape.

5. The transistor array substrate according to claim 1, wherein
a gate electrode of the thin film transistor is formed extending in a direction in which the scan line extends, and
the upper light-blocking film is formed so as to cover above the thin film transistor, and also cover above a portion of the gate electrode positioned outside a region surrounded by the horizontal light-blocking film.

6. The transistor array substrate according to claim 5, wherein
the thin film transistor is further provided with a gate shield electrode formed on a surface side of a semiconductor material layer that makes up the thin film transistor, the surface side being opposite to a surface of the semiconductor material layer on the gate electrode side.

7. The transistor array substrate according to claim 1, wherein
an electrode that makes up the capacitive section includes an electrically-conductive material having a light-blocking property.

8. The transistor array substrate according to claim 1, wherein
a shield electrode is formed above the upper light-blocking film.

9. The transistor array substrate according to claim 8, wherein
a common potential is applied to the shield electrode.

10. The transistor array substrate according to claim 1, wherein
a pixel voltage is applied to the electrode that is the uppermost layer of the capacitive section.

11. The transistor array substrate according to claim 1, wherein
a common potential is applied to the electrode that is the uppermost layer of the capacitive section.

12. The transistor array substrate according to claim 1, wherein
a common potential line and a signal line are further formed above the upper light-blocking film.

13. The transistor array substrate according to claim 1, further comprising:
a pixel electrode to which a pixel voltage held by the capacitive section is applied.

14. A method of manufacturing a transistor array substrate, comprising:
a step of, after a scan line is formed on a support substrate, forming a capacitive section above the scan line and next forming a thin film transistor above the capacitive section;
a step of subsequently forming a wall-shaped horizontal light-blocking film that extends in a normal direction with respect to the support substrate and is in contact with an electrode that is an uppermost layer of the capacitive section, at a perimeter of the thin film transistor; and
a step of next forming an upper light-blocking film above the thin film transistor.

15. A liquid crystal display apparatus comprising:
a transistor array substrate;
a counter substrate disposed so as to oppose the transistor array substrate; and
a liquid crystal material layer enclosed between the transistor array substrate and the counter substrate, wherein
the transistor array substrate includes
a scan line formed on a support substrate,
a capacitive section formed above the scan line, and
a thin film transistor formed above the capacitive section,
a perimeter of the thin film transistor is surrounded by a wall-shaped horizontal light-blocking film that extends in a normal direction with respect to the support substrate and is in contact with an electrode that is an uppermost layer of the capacitive section, and
an upper light-blocking film is formed above the thin film transistor.

16. Electronic equipment comprising:
a liquid crystal display apparatus including
a transistor array substrate,
a counter substrate disposed so as to oppose the transistor array substrate, and
a liquid crystal material layer enclosed between the transistor array substrate and the counter substrate, wherein
the transistor array substrate includes
a scan line formed on a support substrate,
a capacitive section formed above the scan line, and
a thin film transistor formed above the capacitive section,
a perimeter of the thin film transistor is surrounded by a wall-shaped horizontal light-blocking film that extends in a normal direction with respect to the support substrate and is in contact with an electrode that is an uppermost layer of the capacitive section, and
an upper light-blocking film is formed above the thin film transistor.
